(19) United States
(12) Patent Application Publication
(10) Pub. No.: US 2024/0317940 A1
(43) Pub. Date: Sep. 26, 2024

(54) PHOTOIMAGABLE DIELECTRICS

(71) Applicants: ROHM AND HAAS ELECTRONIC MATERIALS LLC, Marlborough, MA (US); DUPONT ELECTRONICS, INC., Wilmington, DE (US)

(72) Inventors: Nora Sabina Radu, Ladenberg, PA (US); Jaclyn Murphy, Ashland, MA (US); Chai Kit Ngai, Chadds Ford, PA (US); Greg A. Hostetler, Newark, DE (US); Qing Min Wang, North Andover, MA (US); Tao Huang, Stow, MA (US); Anton Li, Marlborough, MA (US); Tanya N. Singh-Rachford, South Grafton, MA (US)

(21) Appl. No.: 18/187,072

(22) Filed: Mar. 21, 2023

(51) Int. Cl. C08G 73/10; C08G 73/12; C08J 5/18; C09D 7/47; C09D 7/63; C09D 179/08; H05K 1/03; H05K 3/18

(52) U.S. Cl. CPC C08G 73/1042; C08G 73/1017; C08G 73/1032; C08G 73/1039; C08G 73/1071; C08G 73/127; C08J 5/18; C09D 7/47; C09D 7/63; C09D 179/085; H05K 1/0346; H05K 3/18; C08J 2379/08; H05K 2201/0154

(57) ABSTRACT

There is provided a soluble polyimide resin comprising: (a) one or more tetracarboxylic acid component residues: (b) one or more diamine component residues; and (c) one or more endcapping compounds; wherein: the one or more endcapping compounds comprise one or more crosslinking groups. The soluble polyimide resin can be used in electronics applications.

### FIELD OF THE DISCLOSURE

The present disclosure relates to soluble polyimide resin compositions, methods for preparing such resins, and their use in manufacturing electronic devices.

### BACKGROUND INFORMATION

Polymeric resins are used in spin-on dielectric packaging, circuit boards, laminates, coatings on metallic foils, antenna in package, and other electronic applications. The resins need to provide films/coatings having good mechanical properties and good adhesive properties, as well as low dielectric properties. In particular, it is desirable to have high tensile strength, high tensile elongation, high glass transition temperature (T_{g}), low coefficient of thermal expansion (CTE), good adhesion to copper, and low relative permittivity (Dk) and loss tangent (Df) at high frequencies. In addition, it is desirable to be able to cure the resins at lower temperatures without excessive cure times.

Such a balance of properties may only be available from resin systems that combine multiple polymeric species, fillers, other components, and the like that are designed to modify system properties and/or drive inter-resin reactions. While there are a number of traditional packaging materials that have been employed through the years, polyimides, due to their excellent electrical, mechanical, and thermal properties have been the material of choice for semiconductor packaging applications. There are drawbacks, however, associated with the use of polyimides in such applications—high cure imidization temperature, high CTE, and high levels of water absorption. High CTEs can lead to cured polyimide film shrinkage and an associated high residual stress that causes bowing of the chips' silicon wafers.

Soluble polyimides are known, and photosensitive compositions comprising those polymers have been disclosed. In general, when the molecular weight of the polyimide polymers is low, acceptable photolithographic properties are observed. However, the mechanical properties are degraded to such an extent that compositions employing these polymers cannot be used as advanced packaging materials in packaging processes. When the polyimide molecular weight is increased, acceptable mechanical properties can be achieved. The solubility of the resulting polyimide compositions in a developer can decrease, however, and poor lithographic performance often follows.

Ideal polyimides for photosensitive compositions are not only low loss but are also photo-imageable and compatible with the processing conditions used in packaging applications (i.e., low cure temperature, organic solvent developable). Fully-processed materials should exhibit high elongation, acceptable mechanical properties, and good adhesion to substrates commonly used in advanced packaging applications (e.g., copper, silicon, silicon nitride, etc.).

There is a continuing need for development of such materials in this context.

### DETAILED DESCRIPTION

As used throughout this specification, the following abbreviations shall have the following meanings, unless the context clearly indicates otherwise: ° C.=degree Celsius; g=gram; nm=nanometer, μm=micron=micrometer; mm=millimeter; sec.=second; and min.=minutes. All amounts are percent by weight (“Weight %” or “wt. %”) and all ratios are molar ratios, unless otherwise noted. All numerical ranges are inclusive and combinable in any order, except where it is clear that such numerical ranges are constrained to added up to 100%. Unless otherwise noted, all polymer and oligomer molecular weights are weight average molecular weights (“Mw”) with unit of g/mol or Dalton and are determined using gel permeation chromatography compared to polystyrene standards.

The articles “a”, “an” and “the” refer to the singular and the plural, unless the context clearly indicates otherwise. As used herein, the term “and/or” includes any and all combinations of one or more of the associated items.

As used in herein, R, R^{a}, R^{b}, R′, R″ and any other variables are generic designations and may be the same as or different from those defined in the formulas.

As used herein, the term “addition polymerizable” as it applies to monomers, is intended to mean unsaturated monomers that are capable of polymerization by the simple linking of groups without the co-generation of other products.

The term “adjacent” as it refers to substituent groups that are bonded to carbons that are joined together with a single or multiple bond. Exemplary adjacent R groups are shown below:

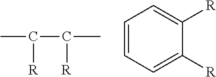

The term “alkoxy” is intended to mean the group RO—, where R is an alkyl group.

The term “alkyl” is intended to mean a group derived from an aliphatic hydrocarbon and includes a linear, a branched, or a cyclic group. A group “derived from” a compound, indicates the radical formed by removal of one or more hydrogen or deuterium. In some embodiments, an alkyl has from 1 to 20 carbon atoms.

The term “amine” is intended to mean a compound that contains a basic nitrogen atom with a lone pair, where lone pair refers to a set of two valence electrons that are not shared with another atom. The term “amino” refers to the functional group —NH₂, —NHR, or —NR₂, where R is the same or different at each occurrence and can be an alkyl group or an aryl group. The term “diamine” is intended to mean a compound that contains two basic nitrogen atoms with associated lone pairs. The term “polyamine” is intended to mean a compound that contains two or more basic nitrogen atoms with associated lone pairs. The term “aromatic diamine” is intended to mean an aromatic compound having two amino groups. The term “aromatic polyamine” is intended to mean an aromatic compound having two or more amino groups. The term “bent diamine” is intended to mean a diamine wherein the two basic nitrogen atoms and associated lone pairs are asymmetrically disposed about the center of symmetry of the corresponding compound or functional group, e.g. m-phenylenediamine:

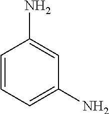

The term “aromatic diamine residue” is intended to mean the moiety bonded to the two amino groups in an aromatic diamine. The term “aromatic polyamine residue” is intended to mean the moiety bonded to the two or more amino groups in an aromatic polyamine. The term “aromatic diisocyanate residue” is intended to mean the moiety bonded to the two isocyanate groups in an aromatic diisocyanate compound. The term “aromatic polyisocyanate residue” is intended to mean the moiety bonded to the two or more isocyanate groups in an aromatic polyisocyanate compound. This is further illustrated below.

| Polyamine/Polyisocyanate | Residue |
|---|---|
| 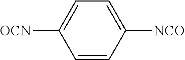 | 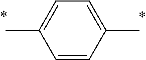 |
| 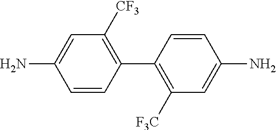 [SMILES: Nc1ccc(-c2ccc(N)cc2C(F)(F)F)c(C(F)(F)F)c1] | 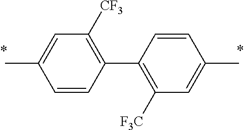 |
| 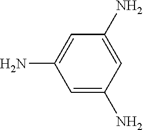 | 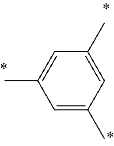 |

The terms “diamine residue” and “diisocyanate residue” are intended to mean the moiety bonded to two amino groups or two isocyanate groups, respectively, where the moiety is aliphatic or aromatic. The terms “polyamine residue” and “polyisocyanate residue” are intended to mean the moiety bonded to two or more amino groups or two or more isocyanate groups, respectively, where the moiety is aliphatic or aromatic.

The term “aromatic compound” is intended to mean an organic compound comprising at least one unsaturated cyclic group having 4n+2 delocalized pi electrons.

The term “aryl” is intended to mean a group derived from an aromatic compound having one or more points of attachment. The term includes groups which have a single ring and those which have multiple rings which can be joined by a single bond or fused together. Carbocyclic aryl groups have only carbons in a ring structure. Heteroaryl groups have at least one heteroatom in a ring structure.

The term “alkylaryl” is intended to mean an aryl group having one or more alkyl substituents.

The term “aryloxy” is intended to mean the group RO—, where R is an aryl group.

The term “crosslinking group” refers to a functional group containing a bond or a short sequence of bonds that are used to connect one polymer chain to another.

The term “curable” as it applies to a composition, is intended to mean a material that becomes harder and less soluble in solvents when exposed to radiation and/or heat, or under the conditions of use.

The term “endcapping compound” refers to a discreet compound or group used in a resin to inhibit ongoing polymerization and thereby control the overall resin molecular weight.

The term “liquid composition” is intended to mean a liquid medium in which a material is dissolved to form a solution, a liquid medium in which a material is dispersed to form a dispersion, or a liquid medium in which a material is suspended to form a suspension or an emulsion.

The term “(meth)acrylate” is intended to mean a group which is either an acrylate or a methacrylate.

The term “polyimide” refers to condensation polymers resulting from the reaction of one or more polyfunctional anhydride components with one or more primary polyamines or polyisocyanates. They contain the imide structure —CO—NR—CO— as a linear or heterocyclic unit along the main chain of the polymer backbone.

The term “semiconductor wafer” is intended to encompass a semiconductor substrate, a semiconductor device, and various packages for various levels of interconnection, including a single-chip wafer, multiple-chip wafer, packages for various levels, substrates for light emitting diodes (LEDs), or other assemblies requiring solder connections. Semiconductor wafers, such as silicon wafers, gallium-arsenide wafers, and silicon-germanium wafers, may be patterned or unpatterned. As used herein, the term “semiconductor substrate” includes any substrate having one or more semiconductor layers or structures which include active or operable portions of semiconductor devices. The term “semiconductor substrate” is defined to mean any construction comprising semiconductive material, such as a semiconductor device. A “semiconductor device” refers to a semiconductor substrate upon which at least one microelectronic device has been or is being fabricated. Thermally stable polymers include, without limitation, any polymer stable to the temperatures used to cure the arylcyclobutene material, such as polyimide, for example, KAPTON™ polyimide (DuPont, Wilmington, DE), liquid crystalline polymers, for example VECSTAR™ LCP film (Kuraray, Tokyo, Japan) and Bismaleimide-Triazine (BT) resins (MGC, Tokyo, Japan). Additional polymeric substrates can include polyolefins such as polyethylene, polypropylene and polyvinyl chloride; a film of polyester such as polyethylene terephthalate (hereinafter may be abbreviated as “PET”) and polyethylene naphthalate, or a polycarbonate film. Further, a release paper, a metal foil such as a copper foil and an aluminum foil, and the like, can be used. The support and a protective film to be described later may be subjected to a surface treatment such as a matte treatment and a corona treatment. Alternatively, the support and the protective film may be subjected to a release treatment with a release agent such as a silicone resin-based release agent, an alkyd resin-based release agent, or a fluororesin-based release agent. In some non-limiting embodiments; the support has a thickness of 10-150 μm, and in some non-limiting embodiments 25-50 μm.

The term “solvent” is intended to mean an organic compound that is a liquid at the temperature of use. The term is intended to encompass a single organic compound or mixture of two or more organic compounds.

The term “tetracarboxylic acid component residue” is intended to mean the moiety bonded to the four carboxy groups in a tetracarboxylic acid component. This is further illustrated below.

| Tetracarboxylic acid component | Residue |
|---|---|
| 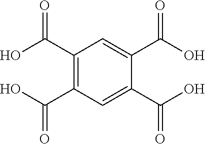 [SMILES: O=C(O)c1cc(C(=O)O)c(C(=O)O)cc1C(=O)O] | 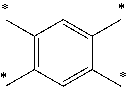 |
| 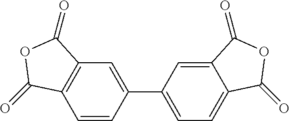 [SMILES: O=C1OC(=O)c2cc(-c3ccc4c(c3)C(=O)OC4=O)ccc21] | 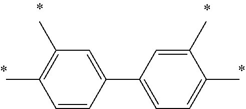 |
| 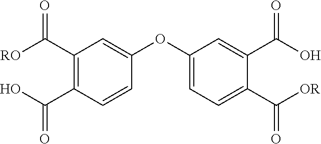 | 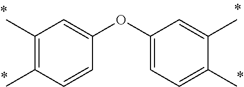 |

The term “thermosetting resin” is intended to refer to a polymer that is liquid or soft that becomes irreversibly crosslinked or experiences irreversible growth in network molecular weight on heating or exposure to radiation such that the material cannot be substantially reshaped after this process.

The terms “film” and “layer” are used interchangeably through this specification.

All ranges are inclusive and combinable. For example, the term “a range of 50 to 3000 cPs, or 100 or more cPs” would include each of 50 to 100 cPs, 50 to 3000 cPs and 100 to 3000 cPs.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof is described as consisting essentially of certain features or elements in which embodiment features or elements that would materially alter the principle of operation or the distinguishing characteristics of the embodiment are not present therein. A further alternative embodiment of the described subject matter hereof is described as consisting of certain features or elements in which embodiment, or in insubstantial variations thereof, only the features or elements specifically stated or described are present.

Unless otherwise defined, all technical and scientific terms used herein have the same meaning as commonly understood by one of ordinary skill in the art to which this disclosure belongs. Although methods and materials similar or equivalent to those described herein can be used in the practice or testing of embodiments of the present disclosure, suitable methods and materials are described below. In addition, the materials, methods, and examples are illustrative only and not intended to be limiting.

To the extent not described herein, many details regarding specific materials, processing acts, and circuits are conventional and may be found in textbooks and other sources within the photoresist, dielectric materials, and semiconductive member arts.

There is provided a soluble polyimide resin comprising: (a) one or more tetracarboxylic acid component residues; (b) one or more diamine component residues; and (c) one or more endcapping compounds; wherein: the one or more endcapping compounds comprise one or more crosslinking groups.

The one or more tetracarboxylic acid component residues are not particularly limited and are derived from the corresponding tetracarboxylic acid dianhydrides selected from the group consisting of aromatic tetracarboxylic acid dianhydrides and aliphatic tetracarboxylic acid dianhydrides.

In some non-limiting embodiments, the aromatic tetracarboxylic acid dianhydrides are selected from the group consisting of 4,4′-(hexafluoro-isopropylidene) diphthalic anhydride (6FDA); 4,4′-oxydiphthalic dianhydride (ODPA); pyromellitic dianhydride (PMDA); 3,3′,4,4′-biphenyltetracarboxylic dianhydride (BPDA); 2,3,3′,4′-biphenyltetracarboxylic dianhydride (s-BDA); asymmetric 2,3,3′,4′-biphenyl-tetracarboxylic dianhydride (a-BPDA); 3,3′,4,4′-benzophenone tetracarboxylic dianhydride (BTDA); 3,3′,4,4′-diphenylsulfone tetracarboxylic dianhydrides (DSDA); 4-(2,5-dioxotetrahydrofuran-3-yl)-1,2,3,4-tetrahydronapthalene-1,2-dicarboyxlic anhydride (DTDA); decahydro-5-(tetrahydro-2,5-dioxo-3-furanyl)naphtho[1,2-c]furan-1,3-dione; hexahydro-4,9-methano-3H-furo[3,4-g][2]benzopyran-1,3,5,7(3aH)-tetrone; 3,3′, 4,4′-bicyclohexyltetracarboxylic dianhydride; hexahydro-4,8-methano-1H,3H-benzo[1,2-c:4,5-c′]difuran-1,3,5,7-tetrone; hexahydro-1H,3H-benzo[1,2-c:4,5-c′]difuran-1,3,5,7-tetrone; 3,3′4,4′-diphenylsulfone tetracarboxylic dianhydride (DSDA); ethylene glycol bis (trimellitic anhydride); 4,4′-bisphenol A dianhydride (BPADA); and the like.

In some non-limiting embodiments, the aromatic tetracarboxylic acid dianhydrides may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

In some non-limiting embodiments, the aliphatic tetracarboxylic acid dianhydrides are selected from the group consisting of cyclobutane dianhydride (CBDA); 3-(carboxymethyl)-1,2,4-cyclopentanetricarboxylic acid 1,4:2,3-dianhydride; bicyclo[2.2.2]oct-7-ene-2,3,5,6-tetracarboxylic dianhydride; 1,2,3,4-cyclopentanetetracarboxylic dianhydride; 1,2,4,5-cyclohexane-tetracarboxylic dianhydride; 1,2,3,4-tetramethyl-1,2,3,4-cyclobutanetetracarboxylic dianhydride; 1,3-dimethyl-1,2,3,4-cyclobutane-tetracarboxylic acid dianhydride; tricyclo-[6.4.0.02,7]dodecane-1,8:2,7-tetracarboxylic dianhydride; meso-butane-1,2,3,4-tetracarboxylic dianhydride; 4-(2,5-dioxotetrahydrofuran-3-yl)-1,2,3,4-tetrahydronaphthalene-1,2-dicarboxylic anhydride; 5-(2,5-dioxotetrahydrofuryl)-3-methyl-3-cyclohexene-1,2-dicarboxylic anhydride; and the like.

In some non-limiting embodiments, the aliphatic tetracarboxylic acid dianhydrides may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

The one or more diamine component residues are not particularly limited and are derived from the corresponding diamines selected from the group consisting of aromatic diamines and aliphatic diamines.

In some non-limiting embodiments, the aromatic diamines are selected from the group consisting of p-phenylenediamine (PPD); 2,2′-bis(trifluoromethyl) benzidine (TFMB); m-phenylenediamine (MPD); 4,4′-oxydianiline (4,4′-ODA), 3,4′-oxydianiline (3,4′-ODA); 2,2-bis(3-amino-4-hydroxyphenyl) hexafluoropropane (BAHFP); 2,2-bis(4-aminophenoxy) hexafluoropropane (HFBAPP); 1,3-bis(3-aminophenoxy) benzene (m-BAPB), 4,4′-bis(4-aminophenoxy) biphenyl (p-BAPB); 2,2-bis(3-aminophenyl) hexafluoropropane (BAPF); bis[4-(3-aminophenoxy)-phenyl]sulfone (m-BAPS); 2,2-bis[4-(4-aminophenoxy)phenyl] sulfone (p-BAPS); m-xylylenediamine (m-XDA); 2,2-bis(3-amino-4-methylphenyl) hexafluoropropane (BAMF); 9,9′-bis(4-aminophenyl) fluorene (FDA), 4,4′-(3,3,3′,3′-tetramethyl-2,2′,3,3′-tetrahydro-1,1′-spirobi[indene]-6,6′-diyl)dianiline, 3,3′-(3,3,3′,3′-tetramethyl-2,2′,3,3′-tetrahydro-1,1′-spirobi[indene]-6,6′-diyl)dianiline, 3,3′-(3,3,3′,3′-tetramethyl-2,2′,3,3′-tetrahydro-1,1′-spirobi[indene]-6,6′-diyl)dianiline, hexamethylenediamines (HMD), 1,4-cyclohexane-diamine (CHDA), 3,3′,5,5′-tetramethyl-4,4′-diamonophenylmethane, 1,3-bis(4-aminophenoxy) benzene; 1,3′-bis(3-aminophenoxy) benzene (APB-133); and the like.

In some non-limiting embodiments, the aromatic diamines may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

In some non-limiting embodiments, the aliphatic diamines are selected from the group consisting of 1,3-bis(aminoethyl) cyclohexane (m-CHDA); 1,4-bis(aminomethyl) cyclohexane (p-CHDA); 1,3-cyclohexanediamine; (8,8′-(4-hexyl-3-octylcyclohexane-1,2-diyl)bis(octan-1-amine); trans 1,4-damino cyclohexane; 4,4′-methylenebi(cyclohexylamine); bis(aminomethyl)norbornane; α-, ω-diaminoalkanes, (e.g., 1,6-hexanediamine; 1,8-octanediamine; 1,12-dodecanediamine); and the like.

In some non-limiting embodiments, the aliphatic diamines may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

The one or more endcapping compounds comprising one or more crosslinking groups are not particularly limited and are selected from the group consisting of aliphatic endcapping compounds, aromatic endcapping compounds, heteroaromatic endcapping compounds, alkynl endcapping compounds, alkenyl endcapping compounds, maleimide endcapping compounds, vinyl endcapping compounds, allylic endcapping compounds, cyanate ester endcapping compounds, ester endcapping compounds, and the like.

In some non-limiting embodiments, the crosslinking groups of the endcapping compounds are selected from the group consisting of radical crosslinking groups, cationic crosslinking groups, anionic crosslinking groups, crosslinking groups capable of forming homopolymers by crosslinking with themselves, crosslinking groups capable of forming heteropolymers by crosslinking with other crosslinking groups, and combinations thereof.

In some non-limiting embodiments, the crosslinking groups of the endcapping compounds are any groups capable of forming carbon-carbon or carbon-heteroatom bonds and are selected from the group consisting of allyl groups, vinyl groups, alkynal groups, alkenyl groups, (meth)acrylate groups, benzocyclobutene groups, maleimide groups, allylic groups, cyanate ester groups, and ester groups.

In some non-limiting embodiments, the one or more endcapping compounds comprising one or more crosslinking groups is selected from the group consisting of 4-ethynylaniline (4-EA), 2,4-diamino-6-diallylamino-1,3,5-triazine (DAMA), 4-amino styrene (4AS), and the like.

In some non-limiting embodiments, the soluble polyimide resin disclosed herein comprises a single tetracarboxylic acid component residue. In some non-limiting embodiments, the soluble polyimide resin disclosed herein comprises two tetracarboxylic acid component residues wherein each tetracarboxylic acid component residue is present in a mole percent between 0.1% and 99.9%; in some non-limiting embodiments, the soluble polyimide resin disclosed herein comprises three tetracarboxylic acid component residues wherein each tetracarboxylic acid component residue is present in a mole percent between 0.1% and 99.9%; in some non-limiting embodiments, the soluble polyimide resin disclosed herein comprises four tetracarboxylic acid component residues wherein each tetracarboxylic acid component residue is present in a mole percent between 0.1% and 99.9%; in some non-limiting embodiments, the soluble polyimide resin disclosed herein comprises five tetracarboxylic acid component residues wherein each tetracarboxylic acid component residue is present in a mole percent between 0.1% and 99.9%; and in some non-limiting embodiments, the soluble polyimide resin disclosed herein comprises six or more tetracarboxylic acid component residues wherein each tetracarboxylic acid component residue is present in a mole percent between 0.1% and 99.9%.

In some non-limiting embodiments, the soluble polyimide resin disclosed herein comprises a single diamine component residue. In some non-limiting embodiments, the soluble polyimide resin disclosed herein comprises two diamine component residues wherein each diamine component residue is present in a mole percent between 0.1% and 99.9%; in some non-limiting embodiments, the soluble polyimide resin disclosed herein comprises three diamine component residues wherein each diamine component residue is present in a mole percent between 0.1% and 99.9%; in some non-limiting embodiments, the soluble polyimide resin disclosed herein comprises four diamine component residues wherein each diamine component residue is present in a mole percent between 0.1% and 99.9%; in some non-limiting embodiments, the soluble polyimide resin disclosed herein comprises five diamine component residues wherein each diamine component residue is present in a mole percent between 0.1% and 99.9%; and in some non-limiting embodiments, the soluble polyimide resin disclosed herein comprises six or more diamine component residues wherein each diamine component residue is present in a mole percent between 0.1% and 99.9%.

In some non-limiting embodiments, the soluble polyimide resin disclosed herein comprises a single endcapping compound; in some non-limiting embodiments two endcapping compounds; in some non-limiting embodiments three endcapping compounds; and in some non-limiting embodiments four or more endcapping compounds.

The amount of the one or more endcapping compounds used in the soluble polyimide resins and/or associated formulations disclosed herein depends upon the targeted properties of interest (e.g., thermal properties, mechanical properties, dielectric properties etc.). In some non-limiting embodiments between 0.1 mol % and 70 mol % of the one or more endcapping compounds are used; in some non-limiting embodiments between 1 mol % and 65 mol %; in some non-limiting embodiments between 5 mol % and 60 mol %; in some non-limiting embodiments between 10 mol % and 50 mol %; in some non-limiting embodiments between 15 mol % and 40 mol %; in some non-limiting embodiments between 20 mol % and 35 mol %; in some non-limiting embodiments between 25 mol % and 30 mol %; in some non-limiting embodiments about 4 mol %; in some non-limiting embodiments about 5 mol %; in some non-limiting embodiments about 6 mol %; in some non-limiting embodiments about 7 mol %; and in some non-limiting embodiments about 8 mol %.

There is further provided a soluble polyimide resin comprising: (a) one or more tetracarboxylic acid component residues; (b) one or more diamine component residues; and (c) one or more endcapping compounds; wherein: the one or more endcapping compounds comprise one or more crosslinking groups; and additionally comprising one or more residues selected from the group consisting of (d) one or more triamine component residues; (e) one or more tetraamine component residues; (f) one or more hexacarboxylic acid trianhydride component residues; and (g) one or more dicarboxylic acid monoanhydrides component residues dicarboxylic acid component residues.

Specific embodiments for the (a) one or more tetracarboxylic acid component residues; (b) one or more diamine component residues; and (c) one or more endcapping compounds; wherein: the one or more endcapping compounds comprise one or more crosslinking groups for these soluble polyimide resins are the same as those disclosed above herein.

The one or more triamine component residues are not particularly limited and are derived from the corresponding triamines selected from the group consisting of aromatic triamines and aliphatic triamines.

In some non-limiting embodiments, the one or more triamines are selected from the group consisting of diethylenetriamine, 4,4′,4″-methanetriyltrianiline, 5′-(4-aminophenyl)-[1,1′:3′,1″-terphenyl]-4,4″-diamine, 4,4′,4″-(1,3,5-triazine-2,4,6-triyl)trianiline, N¹,N¹-bis(4-aminophenyl)benzene-1,4-diamine, N1,N1-bis(3-aminophenyl)benzene-1,3-diamine, 4′-(3-aminophenyl)-[1,1′:2′,1″-terphenyl]-3,3″-diamine, 5′-(3-aminophenyl)-[1,1′:3′,1″-terphenyl]-3,3″-diamine, and 5′-(4-aminophenyl)-[1,1′:3′,1″-terphenyl]-3,3″-diamine.

In some non-limiting embodiments, the triamines may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

The one or more tetraamine component residues are not particularly limited and are derived from the corresponding tetraamines selected from the group consisting of aromatic tetraamines and aliphatic tetraamines.

In some non-limiting embodiments, the one or more tetraamines are selected from the group consisting of tetraaminoethylene, [1,1:3′,1″-terphenyl]-3,3″,5,5″-tetraamine, [1,1′: 4′,1″-terphenyl]-3,3″,5,5″-tetraamine, 5,5′-(1,3,5-triazine-2,4-diyl)bis(benzene-1,3-diamine), 5,5′-(9-methyl-9H-carbazole-3,6-diyl)bis(benzene-1,3-diamine), and 5,5′-(9H-carbazole-3,9-diyl)bis(benzene-1,3-diamine).

In some non-limiting embodiments, the tetraamines may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

The one or more hexacarboxylic acid trianhydride component residues are not particularly limited and are derived from the corresponding tricarboxylic acids selected from the group consisting of aromatic hexacarboxylic acids trianhydrides and aliphatic hexacarboxylic acids trianhydrides.

In some non-limiting embodiments, the one or more hexacarboxylic acids trianhydrides are selected from the group consisting of 5,5′,5″-nitrilotris (isobenzofuran-1,3-dione) and 5,5′,5″-(benzene-1,3,5-triyl)tris(isobenzofuran-1,3-dione).

In some non-limiting embodiments, the hexacarboxylic acid trianhydrides may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

The one or more dicarboxylic acid monoanhydrides component residues are not particularly limited and are derived from the corresponding dicarboxylic acids selected from the group consisting of aromatic dicarboxylic acids and aliphatic dicarboxylic acids.

In some non-limiting embodiments, the one or more dicarboxylic acids monoanhydrides are selected from the group consisting of 5-ethenyl-1,3-isobenzofurandione, 5-ethynylisobenzofuran-1,3-dione, 5-allylisobenzofuran-1,3-dione, 5-(vinyloxy)isobenzofuran-1,3-dione, and 5-(ethynyloxy)isobenzofuran-1,3-dione.

In some non-limiting embodiments, the dicarboxylic acids monoanhydrides may be further substituted with functional groups selected from the group consisting of alkyl; aryl; nitro; cyano; —N(R′)(R″); halo; hydroxy; carboxy; alkenyl; alkynyl; cycloalkyl; heteroaryl; alkoxy; aryloxy; heteroaryloxy; alkoxycarbonyl; perfluoroalkyl; perfluoroalkoxy; arylalkyl; silyl; siloxy; siloxane; thioalkoxy; —S(O)₂—; —C(═O)—N(R′)(R″); (R′)(R″)N-alkyl; (R′)(R″)N-alkoxyalkyl; (R′)(R″)N-alkylaryloxyalkyl; —S(O)ₛ-aryl; and —S(O)ₛ-heteroaryl; and other group capable of forming new C—C or C-heteroatom bonds during the curing process; and wherein: R′ and R″ are the same or different at each occurrence and are an optionally substituted alkyl, cycloalkyl, or aryl group; 0≤S≤2; and the functional groups optionally contain crosslinking groups.

The amount of the one or more one or more residues selected from the group consisting of (d) one or more triamine component residues; (e) one or more tetraamine component residues; (f) one or more tricarboxylic acid component residues; and (g) one or more dicarboxylic acid component residues used in the soluble polyimide resins and/or associated formulations disclosed herein depends upon the targeted properties of interest (e.g., thermal properties, mechanical properties, etc.). In some non-limiting embodiments between 0.1 mol % and 70 mol % of the one or more these residues are used; in some non-limiting embodiments between 1 mol % and 65 mol %; in some non-limiting embodiments between 5 mol % and 60 mol %; in some non-limiting embodiments between 10 mol % and 50 mol %; in some non-limiting embodiments between 15 mol % and 40 mol %; in some non-limiting embodiments between 20 mol % and 35 mol %; in some non-limiting embodiments between 25 mol % and 30 mol %; in some non-limiting embodiments about 4 mol %; in some non-limiting embodiments about 5 mol %; in some non-limiting embodiments about 6 mol %; in some non-limiting embodiments about 7 mol %; and in some non-limiting embodiments about 8 mol %.

Non-limiting examples of the soluble PI resins disclosed herein include:
ODPA//TFMB/APB-133/4AS 100//49/49/4;
ODPA//TFMB/APB-133/DAMA/4AS 100//46.5/46.5/5/4;
BPADA//APB-133/TFMB/4AS 100//42.5/42.5/30;
BPADA//APB-133/TFMB/4AS 100//45/45/20;
ODPA/6FDA//TFMB/Priamine™ 1075/4-AS 85/15//91/05/08;
ODPA//APB-133/TFMB/DAMA/4-EA 100//46.5/46.5/05/04;
ODPA//APB-133/TFMB/M1309/4-AS 100//46/46/04/08;
BPADA//APB-133/4-AS 100//85/30; and
BPADA//APB133/TFMB/1-(4-aminophenyl)-1H-pyrrole-2,5-dione) 100//42.5/42.5/30

Solutions containing the soluble polyimide resins disclosed herein may be prepared using a variety of available methods with respect to how the components (i.e., the monomers and solvents) are introduced to one another. Numerous variations of producing a soluble polyimide resin solution include:
(1) a method wherein the diamine components and dianhydride components are preliminarily mixed together and then the mixture is added in portions to a solvent while stirring.
(2) a method wherein a solvent is added to a stirring mixture of diamine and dianhydride components (contrary to (a) above).
(3) a method wherein diamines are exclusively dissolved in a solvent and then dianhydrides are added thereto at such a ratio as allowing to control the reaction rate.
(4) a method wherein the dianhydride components are exclusively dissolved in a solvent and then amine components are added thereto at such a ratio to allow control of the reaction rate.
(5) a method wherein the diamine components and the dianhydride components are separately dissolved in solvents and then these solutions are mixed in a reactor.
(6) a method wherein the polyamic acid with excessive amine component and another polyamic acid with excessive dianhydride component are preliminarily formed and then reacted with each other in a reactor, particularly in such a way as to create a non-random or block copolymer.
(7) a method wherein a specific portion of the amine components and the dianhydride components are first reacted and then the residual diamine components are reacted, or vice versa.
(8) a method wherein the components are added in part or in whole in any order to either part or whole of the solvent, also where part or all of any component can be added as a solution in part or all of the solvent.
(9) a method of first reacting one of the dianhydride components with one of the diamine components giving a first polyamic acid. Then reacting the other dianhydride component with the other amine component to give a second polyamic acid. Then combining the amic acids in any one of a number of ways prior to film formation.

Generally speaking, a solution containing a soluble polyimide resin can be derived from any one of the preparation methods disclosed above or other similar methods as practiced by those having skill in the art.

The choice of particular solvent or solvents to use is generally not limited and can be selected by one having skill in the art. High-boiling, polar, aprotic solvents are often preferred. Non-limiting examples of such solvents include N-methyl-2-pyrrolidone (NMP), dimethyl acetamide (DMAc), dimethyl sulfoxide (DMSO), dimethyl formamide (DMF), butyrolactone, dibutyl carbitol, butyl carbitol acetate, diethylene glycol monoethyl ether acetate, propylene glycol monomethyl ether acetate, and the like and combinations thereof.

A non-limiting example of a method for preparing a soluble polyimide resin includes performing the following steps in order: (a) dissolving one or more diamines in a high-boiling, polar, aprotic solvent; (b) adding one or more endcapping compounds to the solution prepared in (a); (c) adding one or more dianhydrides to the solution prepared in (b); (d) stirring the solution prepared in (c) for a first predetermined period of time; (e) heating the solution prepared in (d) to a first predetermined temperature and optionally adding a solution of one or more imidization catalysts; (f) heating the solution prepared in (e) to a second predetermined temperature and stirring for a second predetermined period of time; and (g) cooling the solution prepared in (f) and isolating the solid polyimide resin.

In some non-limiting embodiments of the method disclosed herein, one or more additional solutions are stepwise-added to the solution prepared in step (c) above. In some non-limiting embodiments the additional solutions are 10 mol % or less in one or more dianhydrides, in some non-limiting embodiments 5 mol % in one or more dianhydrides, and in some non-limiting embodiments 2.5 mol % or less in one more dianhydrides.

In some non-limiting embodiments of the method disclosed herein, the one or more imidization catalysts used in step (e) are selected from the group consisting of aliphatic acid anhydrides, acid anhydrides, alcohol/acid cocatalysts, aliphatic tertiary amines, aromatic tertiary amines, and heterocyclic tertiary amines.

In some non-limiting embodiments of the method disclosed herein, thermal conversion processes may be used which may or may not employ conversion chemicals (i.e., catalysts) to convert a polyamic acid casting solution to a polyimide. If conversion chemicals are used, the process may be considered a modified-thermal conversion process. In both types of thermal conversion processes, only heat energy is used to heat the film to both dry the film of solvent and to perform the imidization reaction. Thermal conversion processes with or without conversion catalysts are generally used to prepare the polyimide films disclosed herein.

Specific method parameters are pre-selected considering that it is not just the film composition that yields the properties of interest. Rather, the cure temperature and temperature-ramp profile also play important roles in the achievement of the most desirable properties for the intended uses disclosed herein. The polyamic acids should be imidized at a temperature at, or higher than, the highest temperature of any subsequent processing steps (e.g. deposition of inorganic or other layer(s) necessary to produce a functioning display), but at a temperature which is lower than the temperature at which significant thermal degradation/discoloration of the polyimide occurs. It should also be noted that an inert atmosphere is generally preferred, particularly when higher processing temperatures are employed for imidization.

For the polyamic acids/polyimides disclosed herein, temperatures of 300° C. to 400° C. are typically employed when subsequent processing temperatures in excess of 300° C. are required. Choosing the proper curing temperature allows a fully cured polyimide which achieves the best balance of thermal and mechanical properties. Because of this very high temperature, an inert atmosphere is required. Typically, oxygen levels in the oven of <100 ppm should be employed. Very low oxygen levels enable the highest curing temperatures to be used without significant degradation/discoloration of the polymer. Catalysts that accelerate the imidization process are effective at achieving higher levels of imidization at cure temperatures between about 200° C. and 300° C. This approach may be optionally employed if the flexible device is prepared with upper cure temperatures that are below the T_{g} of the polyimide.

The amount of time in each potential cure step is also an important process consideration. Generally, the time used for the highest-temperature curing should be kept to a minimum. For 320° C. cure, for example, cure time can be up to an hour or so under an inert atmosphere; but at higher cure temperatures, this time should be shortened to avoid thermal degradation. Generally speaking, higher temperature dictates shorter time. Those skilled in the art will recognize the balance between temperature and time in order to optimize the properties of the polyimide for a particular end use.

In a specific embodiment, a soluble polyimide resin may be prepared by introducing nitrogen gas into a three-necked reaction vessel equipped with a PTFE stirring shaft, O-ring, and a bearing assembly to provide an inert atmosphere. The desired amino compounds can be dissolved in DMAc at room temperature for most diamines. In certain examples, the DMAC may be warmed to an appropriate temperature to dissolve all of the diamines added. To the stirring solution of diamine(s), the desired dianhydride monomers may be added portion-wise to the reaction mixture such that the internal temperature does not exceed the desired temperature. The reaction mixture may then be stirred until the resulting polyamic acid solution was within the desired viscosity range.

To the polyamic acid solution, acetic anhydride and β-picoline can then be added. The reaction mixture may be heated to 80° C., and the reaction may be held at that temperature for approximately 3 h and then stirred overnight. The resulting polyimide can then be isolated as a powder by precipitation from water and/or additional precipitation cosolvents such as methanol, acetone, etc. The polymer may be rinsed with methanol and dried. The polyimide can be isolated as a white powder and characterized by GPC and NMR spectroscopy. Specific embodiments, and variations thereof, are presented in the Examples.

The soluble polyimide resins prepared as disclosed herein generally possess a number of mechanical, electronic, and thermal properties that make them well suited for use in the electronic applications disclosed herein. In some non-limiting embodiments, the soluble polyimide resins have: (a) Mn less than 80,000; (b) Mw less than 150,000; (c) a loss tangent less than 0.007; and (d) a coefficient of thermal expansion less than 50 ppm/K.

In some non-limiting embodiments; Mn of the soluble PI resins disclosed herein is less than 70,000, in some non-limiting embodiments less than 60,000, in some non-limiting embodiments less than 50,000, in some non-limiting embodiments less than 40,000, in some non-limiting embodiments less than 30,000, in some non-limiting embodiments less than 20,000, and in some non-limiting embodiments less than 10,000.

In some non-limiting embodiments; Mw of the soluble PI resins disclosed herein is less than 140,000, in some non-limiting embodiments less than 1300,000, in some non-limiting embodiments less than 120,000, in some non-limiting embodiments less than 110,000, in some non-limiting embodiments less than 100,000, in some non-limiting embodiments less than 90,000, in some non-limiting embodiments less than 80,000, in some non-limiting embodiments less than 70,000, in some non-limiting embodiments less than 60,000, in some non-limiting embodiments less than 50,000, in some non-limiting embodiments less than 40,000, in some non-limiting embodiments less than 30,000, in some non-limiting embodiments less than 20,000, and in some non-limiting embodiments less than 10,000.

In some non-limiting embodiments; the loss tangent (Df) of the soluble PI resins disclosed herein is less than 0.006, in some non-limiting embodiments less than 0.005, in some non-limiting embodiments less than 0.004, in some non-limiting embodiments less than 0.003, in some non-limiting embodiments less than 0.002, and in some non-limiting embodiments less than 0.001.

In some non-limiting embodiments; the coefficient of thermal expansion (CTE) of the soluble PI resins disclosed herein is less than 40 ppm/K, in some non-limiting embodiments less than 30 ppm/K, in some non-limiting embodiments less than 20 ppm/K, and in some non-limiting embodiments less than 10 ppm/K.

There is further provided a liquid composition comprising two or more of the following: (a) 15-90 weight % of one or more soluble polyimide resins; (b) 5-75 weight % of one or more crosslinking compounds; (c) 0-5 weight % of one or more photoinitiators or thermal radical initiators; (d) 0-5 weight % of one or more oxidation catalysts; and (e) 0-65 weight % of one or more solvents.

Specific embodiments for the one or more soluble polyimide resins are the same as those disclosed above herein.

Any suitable crosslinking compound (“crosslinker”) may be used in the present liquid compositions. A suitable crosslinker may react with functional groups in the resin composition, including alkenes, functional groups that undergo free radical curing mechanisms, Michael reactions, and Diels Alder dienes as chosen by one skilled in the art. Such suitable crosslinkers may include multifunctional thiols, multifunctional azides, multifunctional azirines, and bis-arylcyclobutene monomers as well as multifunctional dienophiles such as (meth)acrylates, di(meth)acrylates, maleimides, bismaleimides, multifunctional maleimides, allyl compounds, diallyl compounds, vinyl silane compounds, divinyl compounds, cyanate esters, and di-, tri-, and multifunctional amines, or other suitable dienophiles, provided that they crosslink with the polymer of the present disclosure under the conditions used to cure the composition. The selection of such crosslinkers is within the ability of those skilled in the art.

In some non-limiting embodiments, the one or more crosslinkers are selected from the group consisting of multifunctional thiols, multifunctional azides, multifunctional azirines, bis-arylcyclobutenes, (meth)acrylates, maleimides, allyl compounds, vinyl or other alkenyl compounds, vinyl silane compounds, dienophiles and other suitable reaction partners. In some non-limiting embodiments, the one or more crosslinkers are (meth)acrylates. In some non-limiting embodiments, the one or more crosslinkers are maleimides. In some non-limiting embodiments, the maleimides comprise one or more biphenyl groups or long-chain aliphatic groups. In some non-limiting embodiments the one or more crosslinkers are selected from the group consisting of MIR3000, MIR5000, BMI4000, BMI5100, BMI-TMH, BMI689, SR454, triallyl isocyanurate (TAIC), triallyl cyanurate (TAC), and SPV-100.

In some non-limiting embodiments, the liquid compositions disclosed herein contain 5-75 weight % of one or more crosslinkers, in some non-limiting embodiments 10-60 weight %, in some non-limiting embodiments 15-50 weight %, in some non-limiting embodiments 20-40 weight %, and in some non-limiting embodiments 12-18 weight %.

Any suitable photoinitiators or thermal radical initiator may be used as a curing agent in the present liquid compositions. A variety of curing agents may be used in the liquid compositions of the present disclosure which are useful in photolithography. Suitable curing agents may aid in the curing of the polyimide containing materials and may be activated by heat or light. Exemplary curing agents can include, but are not limited to, thermally generated initiators and photoactive compounds (photogenerated initiators). The selection of such curing agents is within the ability of those skilled in the art. Preferred thermal generated initiators are free radical initiators, such as, but not limited to, azobisisobutyronitrile, dibenzoyl peroxide, and dicumylperoxide (DCP). In some non-limiting embodiments, photoinitiators are selected from the group consisting of acylphosphine oxides, alpha-aminioalkylphenones, alpha-dialkyloxyacetonephenones, and oxime esters. Preferred photoactive curing agents are free radical photoinitiators available from BASF under the Irgacure brand, and diazonaphthoquinone (DNQ) compounds including sulfonate esters of a DNQ compound. Suitable DNQ compounds are any compounds having a DNQ moiety, such as a DNQ sulfonate ester moiety, and that function as photoactive compounds in the present compositions, that is, they function as dissolution inhibitors upon exposure to appropriate radiation. Suitable DNQ compounds are disclosed in U.S. Pat. Nos. 7,198,878 and 8,143,360, the entire contents of which are incorporated herein by reference.

The amount of photoinitiator or thermal initiator varies from 0 to 30 wt. %, based on the total weight of the polymer solids. When present, the photoactive compound is typically used in an amount of 5 to 30 wt. %, or from 5 to 25 wt. %, or from 10 to 25 wt. %, based on the total weight of polymer solids.

Any suitable oxidation catalyst may be used in the present liquid compositions. In some non-limiting embodiments, the one or more oxidation catalysts are selected from the group consisting of TEMPO, 4-hydroxy-TEMPO, 4-amino-TEMPO, alkylated-hydroquinone, alkylated hydroxytoluene, alkylated hydroxyanisole, and others as would be known to one having skill in the art.

The amount of oxidation catalyst varies from 0 to 30 wt. %, based on the total weight of the polymer solids. When present, the oxidation catalyst is typically used in an amount of 5 to 30 wt. %, or from 5 to 25 wt. %, or from 10 to 25 wt. %, based on the total weight of polymer solids.

Any suitable solvent may be used in the present liquid compositions so long as the components of the compositions are soluble or dispersible therein. Non-limiting embodiments of the one or more solvents include cyclopentanone, cyclohexanone, propylene glycol monomethyl ether, propylene glycol monomethyl ether acetate, gamma-butyrolactone, 3-methoxypropionate, dipropylene glycol dimethyl ether, 3-methoxybutyl acetate, anisole, mesitylene, 2-heptanone, cyrene, 2-butanone, ethyl lactate, amyl acetate, n-butyl acetate, n-methyl-2-pyrrolidone, N-butyl-2-pyrrolidone, 2-butanone, toluene, acetone, methylethylketone, and the like and combinations thereof.

The solvent can be present in an amount of 10-90 wt. %, or 20-80 wt. %, or 30-70 wt. %, or 40-60 wt. % based on the total weight of the components of the liquid composition.

There is further provided a liquid composition as described herein above and additionally comprising one or more of the following: (f) one or more additional resins in an amount of 10-60 60 wt. %; (g) one or more surface leveling agents in an amount of 0-10 wt %; (h) one or more organic or inorganic fillers in an amount of 0-70 wt. % and (i) 0-25 wt. % of one or more adhesion promoters.

Specific embodiments for the (a) 15-90 weight % of one or more soluble polyimide resins; (b) 5-75 weight % of one or more crosslinking compounds; (c) 0-5 weight % of one or more photoinitiators or thermal radical initiators; (d) 0-5 weight % of one or more oxidation catalysts; and (e) 0-65 weight % of one or more solvents are the same as those disclosed above herein.

The use of additional resins in the compositions disclosed herein can provide materials with optimized properties for the targeted electronic formulations. Non-limiting examples of the additional resins include MIR-3000, NC-3000, epoxy resins, novolac resins and others as would be known to those with skill in the art. When present, the additional resins can be present in an amount from 0.5-60 wt. %, or 1-40 wt. %, or 5-30 wt. %, or 10-20 wt. %.

Any suitable surface leveling agent or ‘leveling agent’ may be used in the liquid compositions of the present disclosure and the selection of such is well within the ability of those skilled in the art. The leveling agent may contain a majority of silicone units derived from the polymerization of the following monomers Si(R¹)(R²)(OR³)₂ wherein R¹, R² or R³ is each independently chosen from a C₁-C₂₀ alkyl or a C₅-C₂₀ aliphatic group or a C₁-C₂₀ aryl group. In one non-limiting embodiment, the leveling agent is non-ionic and may contain at least two functional groups that can chemically react with functional groups contained in the silicon and non-silicon resins under a cationic photo curing process or thermal curing condition. A leveling agent containing non-reactive groups is present in some non-limiting embodiments. In addition to silicon-derived units the leveling agent may comprise units derived from the polymerization of an C₃-C₂₀ aliphatic molecule comprising an oxirane ring. In addition, the leveling agent may comprise units derived from an C₁-C₅₀ aliphatic molecule comprising a hydroxyl group. In some non-limiting embodiments, the leveling agent is free of halogen substituents. In some non-limiting embodiments, the molecular structure of the leveling agent is predominantly linear, branched, or hyperbranched, or it may be a graft structure.

In some non-limiting embodiments; the leveling agent is selected from the group consisting of, AD1700, MD700; Megaface F-114, F-251, F-253, F-281, F-410, F-430, F-477, F-510, F-551, F-552, F-553, F-554, F-555, F-556, F-557, F-558, F-559, F-560, F-561, F-562, F-563, F-565, F-568, F-569, F-570, F-574, F-575, F-576, R-40, R-40-LM, R-41, R-94, RS-56, RS-72-K, RS-75, RS-76-E, RS-76-NS, RS-78, RS-90, DS-21 (DIC Sun Chemical); KY-164, KY-108, KY-1200, KY-1203 (Shin Etsu); Dowsil 14, Dowsil 11, Dowsil 54, Dowsil 57, Dowsil FZ2110, FZ-2123; Xiameter OFX-0077; ECOSURF EH-3, EH-6, EH-9, EH-14, SA-4, SA-7, SA-9, SA-15; Tergitol 15-S-3, 15-S-5, 15-S-7, 15-S-9, 15-S-12, 15-S-15, 15-S-20, 15-S-30, 15-S-40, L61, L-62, L-64, L-81, L-101, XD, XDLW, XH, XJ, TMN-3, TMN-6, TMN-10, TMN-100X, NP-4, NP-6, NP-7, NP-8, NP-9, NP-9.5, NP-10, NP-11, NP-12, NP-13, NP-15, NP-30, NP-40, NP-50, NP-70; Triton CF-10, CF-21, CF-32, CF76, CF87, DF-12, DF-16, DF-20, GR-7M, BG-10, CG-50, CG-110, CG-425, CG-600, CG-650, CA, N-57, X-207, HW 1000, RW-20, RW-50, RW-150, X-15, X-35, X-45, X-114, X-100, X-102, X-165, X-305, X-405, X-705; PT250, PT700, PT3000, P425, P1000 TB, P1200, P2000, P4000, 15-200 (Dow Chemical); DC ADDITIVE 3, 7, 11, 14, 28, 29, 54, 56, 57, 62, 65, 67, 71, 74, 76, 163 (Dow Silicones); TEGO Flow 425, Flow 370, Glide 100, Glide 410, Glide 415, Glide 435, Glide 432, Glide 440, Glide 450, Flow 425, Wet 270, Wet 500, Rad 2010, Rad 2200 N, Rad 2011, Rad 2250, Rad 2500, Rad 2700, Dispers 670, Dispers 653, Dispers 656, Airex 962, Airex 990, Airex 936, Airex 910 (Evonik); BYK-300, BYK-301/302, BYK-306, BYK-307, BYK-310, BYK-315, BYK-313, BYK-320, BYK-322, BYK-323, BYK-325, BYK-330, BYK-331, BYK-333, BYK-337, BYK-341, BYK-342, BYK-344, BYK-345/346, BYK-347, BYK-348, BYK-349, BYK-370, BYK-375, BYK-377, BYK-378, BYK-UV3500, BYK-UV3510, BYK-UV3570, BYK-3550, BYK-SILCLEAN 3700, Modaflow® 9200, Modaflow® 2100, Modaflow® Lambda, Modaflow® Epsilon, Modaflow® Resin, Efka FL, Additiol XL 480, Additol XW 6580, and BYK-STLCLEAN 3720.

In some non-limiting embodiments, the leveling agent can be present in an amount of from 0 to 10 wt %, or from 0 to 5 wt %, or from 0 to 1 wt %, or from 0.001 to 0.9 wt %, or from 0.05 to 0.5 wt %, or from 0.05 to 0.25 wt %, or from 0.05 to 0.2 wt %, or from 0.1 to 0.15 wt %.

In some non-limiting embodiments of the liquid compositions disclosed herein, the at least one or two inorganic particulate fillers are selected from the group consisting of inorganic fillers having dielectric constants of less than 5 and dielectric loss (in GHz range) of less than 0.002. Any particulate filler with these properties is generally useful, as long as it is less than about 2 μm average size or about 8 μm absolute size, and has good insulative properties, and/or good dielectric properties. In some non-limiting embodiments, the inorganic particulate filler preferably has an average particle size of less than or equal to ten percent of the layer thickness of the dielectric composite material in the final product. In some non-limiting embodiments, the inorganic particulate filler has a dielectric constant of less than or equal to 4.0, and a dielectric loss of less than 0.001. Non-limiting examples of inorganic particulate fillers include silica, alumina, boron nitride, glass, and quartz.

In some non-limiting embodiments of the liquid compositions disclosed herein, the at least one inorganic particulate filler is surface modified via reaction with one or more silane coupling agents. the selection of silane coupling agents used for surface modification of the at least one inorganic particulate filler is not particularly limited. In some non-limiting embodiments of the dielectric composite material disclosed herein, the one or more acrylic-based silane coupling agents has a structure given by Formula

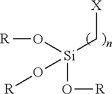

where R is the same or different at each occurrence and is selected from the group consisting of alkyl, aryl, acetyl, ketimino, and alkenyl; X is an unsaturated group selected from the group consisting of acryloxy, methacryloxy, allyloxy, vinyl, maleimido, fumarate ester, maleate ester, ethynyl, phenylethynyl, phenylamino, phenyl, stilbene, propiolate and phenylpropiolate ester; and n is an integer from 0-10. In some non-limiting embodiments, the silane coupling agent is acrylic-based. In some non-limiting embodiments, the silane coupling agent is monomeric, and in some non-limiting embodiments the silane coupling agent is polymerized through a vinyl group.

Examples of the acrylic-based silane coupling agents can include, but are not limited to, bis(trimethoxysilyl)propyl fumarate, 8-methacryloxyoctyl-trimethoxysilane (KBM-5803), acryloxy and methyl methoxy silane oligomer (KR-513), methacryloxy and methyl methoxy silane oligomer (X-40-9296), mercapto and methyl methoxy silane oligomer (KR-519), mercapto methoxy silane organic chain oligomer (X-12-1154), and 3-methacryloxypropy trimethoxy silane (KBM-503), 3-methacryloxypropy methyldimethoxy silane (KBM-502), 3-methacryloxypropy triethoxy silane (KBE-503), N-phenyl-3-amino propyl trimenthoxy silane (KBM-573), and phenyl trimethoxy silane (KBM-103).

In some non-limiting embodiments of the dielectric composite material disclosed herein, the one or more acrylic-based silane coupling agents is combined with one or more polymeric silanes for surface modification of the inorganic particulate filler. In some non-limiting embodiments, the one or more polymeric silanes has a structure given by Formula

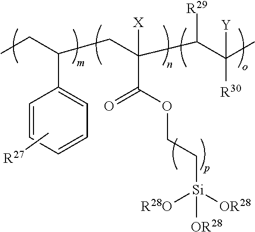

where R²⁷ is selected from the group consisting of alkyl and H; R²⁸ is selected from the group consisting of alkyl and aryl, acetyl, ketimino, and alkenyl; R²⁹ is selected from the group consisting of COOCH₂CH═CH₂, CH₃, and H; R³⁰ is selected from the group consisting of 4-allyloxyphenyl, COOCH₂CH═CH₂ and any group containing a reactive dienophile; X and Y are the same or different and are selected from the group consisting of methyl and H; m and n are the same or different and are an integer from 10-1000; o is an integer from 0-1000; and p is an integer from 0-10.

In some non-limiting embodiments, the liquid compositions disclosed herein contain 0-80 weight % of one or more inorganic particular fillers, in some non-limiting embodiments 20-75 weight %, in some non-limiting embodiments 40-72 weight %, and in some non-limiting embodiments 54-68 weight %.

In some non-limiting embodiments, the liquid compositions disclosed herein comprise one or more organic particulate fillers which may be rubber particles or the like. The rubber particles are not soluble even in an organic solvent used for the preparation of the disclosed resin compositions and are also immiscible with components in the resin composition such as an arylcyclobutene resin. Accordingly, the rubber particles in the present invention are present in a dispersed state in a varnish of the disclosed resin composition. Such rubber particles are usually prepared by making the molecular weight of the rubber component high to such a level that they are not dissolved in organic solvents and resin and by making into particles. For example, a rubber component which is soluble in a solvent and is miscible with other component such as arylcyclobutene resin in the resin composition is compounded, roughness after the roughening treatment greatly increases and heat resistance of the cured product also lowers.

Non-limiting examples of the rubber particles in the present invention include core-shell type rubber particles, cross-linked acrylonitrile butadiene rubber particles, cross-linked styrene butadiene rubber particles, and acrylate rubber particles. Core-shell type rubber particles are rubber particles where the particle has a core layer and a shell layer and its examples are a two-layered structure where the shell layer which is an outer layer is glass-like polymer and the core layer which is an inner layer is a rubber-like polymer and a three-layered structure where the shell layer which is an outer layer is a glass-like polymer, an intermediate layer is a rubber-like polymer and the core layer is a glass-like polymer. The glass layer is constituted, for example, from a polymer of methyl methacrylate while the rubber-like polymer layer is constituted, for example, from a polymer of butyl acrylate (butyl rubber). Specific examples of the core-shell type rubber particles include Staphyloid AC 3832 and AC 3816 N (trade name; Ganz Chemical Co., Ltd.) and Metablen KW-4426 (trade name; Mitsubishi Rayon Co., Ltd.). Specific examples of the acrylonitrile butadiene rubber (NBR) particles include XER-91 (average particle size: 0.5 μm; manufactured by JSR Co.), etc. Specific examples of the styrene butadiene rubber (SBR) particles include XSK-500 (average particle size: 0.5 μm; manufactured by JSR Co.), etc. Specific examples of the acrylate rubber particles include Metablen W300A (average particle size: 0.1 μm) and W450A (average particle size: 0.2 μm) (manufactured by Mitsubishi Rayon Co., Ltd.). Such rubber particles are able to bestow the effects such as enhancing the mechanical strength of cured product, mitigating the stress of the cured product, etc.

An average particles size of the rubber particles to be compounded is generally within a range of 0.005 to 1 m and, in some non-limiting embodiments, within a range of 0.2 to 0.6 m. Average particle size of the rubber particles in the present invention is able to be measured using a dynamic light scattering method. The measurement is carried out, for example, in such a manner that rubber particles are uniformly dispersed by an ultrasonic wave, etc. in an appropriate organic solvent, particle size distribution of the rubber particles is prepared on the basis of mass using an FPRA-1000 (manufactured by Otsuka Electronics Co., Ltd.) and a median diameter thereof is adopted as an average particle size.

In some non-limiting embodiments, the liquid compositions disclosed herein contain 0-80 weight % of one or more organic particular fillers, in some non-limiting embodiments 20-75 weight %, in some non-limiting embodiments 40-72 weight %, and in some non-limiting embodiments 54-68 weight %.

Any suitable adhesion promoter may be used in the liquid compositions of the present disclosure and the selection of such is well within the ability of those skilled in the art. In some non-limiting examples, adhesion promoters are silane-containing materials or tetraalkyl titanates, or trialkoxysilane-containing materials. Exemplary adhesion promoters include, but are not limited to, bis(trialkoxysilylalkyl)benzenes such as bis(trimethoxysilylethyl)benzene; aminoalkyl trialkoxy silanes such as aminopropyl trimethoxy silane, aminopropyl triethoxy silane, and phenyl aminopropyl triethoxy silane; and other silane coupling agents, as well as mixtures of the foregoing. In some non-limiting embodiments, the adhesion promoters used are selected from the group consisting of dienophiles. Adhesion promoters may be applied first as a primer layer or as an additive to the composition. Some non-limiting examples of appropriate adhesion promoters include AP 3000, AP 8000, and AP 9000C (DuPont de Nemours, Wilmington, DE).

Other suitable adhesion promoters include organo-phosphorous compounds that may or may not contain other heteroatoms. Such species are not particularly limited and are generally selected from the group consisting of organophosphorous compounds of P(III), P(V), and derivatives thereof.

Non-limiting examples of organophosphorus compounds of P(III) include phosphines (PR₃, including alkyldiaryl phosphines, bidentate alkyldiaryl-phosphines, bidentate triarylphosphines, dialkylarylphosphines, trialkylphosphines, triarylphosphines), aminophosphines (PR₂(NR₂)), phosphinites (PR₂(OR)), diaminophosphines (PR(NR₂)₂), phosphonamidites (PR(OR)(NR₂), phosphonites (PR(OR)₂, including dialkylaryl phosphonites and bidentate aryl phosphonites), triamino-phosphines (P(NR₂)₃), phosphoro-diamidites (P(OR)(NR₂)₂), phosphoramidites (P(OR)₂(NR₂), and phosphites (P(OR)₃, including triaryl phosphites and bidentate aryl phosphites). Generally, in these P(III) compounds, R is selected from the group consisting of hydrogen, a substituted or unsubstituted (C₁-C₃₀)alkyl, a substituted or unsubstituted (C₂-C₃₀)alkenyl, a substituted or unsubstituted (C₅-C₃₀)aryl, a substituted or unsubstituted 5- to 30-membered heteroaryl, or CN; or may be linked to an adjacent substituent to form a substituted or unsubstituted mono- or polycyclic, (C₅-C₃₀) alicyclic or aromatic ring, whose carbon atom(s) may be replaced with at least one heteroatom selected from nitrogen, oxygen, sulfur, Si, PO, SO, SO₂, and SeO₂.

In some non-limiting embodiments of organophosphorus compounds of P(III) at least one of R is a C₁-C₃₀ alkyl, in some embodiments all R's are C₁-C₃₀ alkyl.

Non-limiting examples of organophosphorus compounds of P(V) include phosphine oxides (PR₃(O), including trialkyl phosphine oxides and triaryl phosphine oxides), phosphinates (PR₂(O)(OR), including aryl phosphinic acids and dialkyl phosphinic acids), phosphinamides (PR₂(0)(NR₂)), phosphonates (PR(O)(OR)₂, including trialkyl phosphonates, triaryl phosphonates, and dialkylaryl phosphonates), phosphonamidates (PR(O)(OR)(NR₂)), phosphonamides (PR(O)(NR₂)₂), phosphates (P(O)(OR)₃, including alkyl phosphoric acids), phosphor-amidates (P(O)(OR)₂(NR₂)), phosphorodiamidates (P(O)(OR)(NR₂)₂), and phosphoramides (P(O)(NR₂)₃). Generally, in these P(V) compounds R is the same or different at each occurrence and selected from the group consisting of hydrogen, a substituted or unsubstituted (C₁-C₃₀)alkyl, a substituted or unsubstituted (C₂-C₃₀)alkenyl, a substituted or unsubstituted (C₅-C₃₀)aryl, a substituted or unsubstituted 5- to 30-membered heteroaryl, or CN; or may be linked to an adjacent substituent to form a substituted or unsubstituted mono- or polycyclic, (C₅-C₃₀) alicyclic or aromatic ring, whose carbon atom(s) may be replaced with at least one heteroatom selected from nitrogen, oxygen, sulfur, Si, PO, SO, SO₂, and SeO₂.

In some non-limiting embodiments of organophosphorus compounds of P(V) at least one of R is a C₁-C₃₀ alkyl, in some embodiments all R's are C₁-C₃₀ alkyl. In some non-limiting embodiments, the organo-phosphorous compounds may be phosphate ester amide compounds such as SP670 and SP703 (Shikoku Chemicals Corporation), phosphazene compounds such as SPB-100, SPV-100 and SPE-100 (Otsuka Chemical Co., Ltd.), and FP-series (FUSHIMI Pharmaceutical Co., Ltd.). Potentially useful metal hydroxides include magnesium hydroxide such as UD65, UD650, and UD653 (Ube Material Industries, Ltd.), and aluminum hydroxide such as B-30, B-325, B-315, B-308, B-303, and UFH-20 (Tomoe Engineering Co., Ltd.).

Preferred adhesion promoters can include those capable of crosslinking to one or more components of the disclosed coating formulations. Such adhesion promoters include one or more functional groups selected from the group consisting of vinyl, styryl, maleimide, acrylic, methacrylic, allylic, alkynyl, or the functional equivalent.

The liquid compositions of the present disclosure may contain from 0 to 25 wt. %, or from 1 to 20 wt. %, or from 2 to 15 wt. %, or from 5 to 10 wt. % of an adhesion promoter based on the total weight of the composition.

There is further provided a crosslinked resin comprising one or more of the liquid compositions disclosed herein.

Specific embodiments for the components of the crosslinked resin are the same as those disclosed above herein.

The crosslinked resins prepared as disclosed herein generally possess a number of mechanical, electronic, and thermal properties that make them well suited for use in the electronic applications disclosed herein. In some non-limiting embodiments, the crosslinked resins exhibit: (1) a coefficient of thermal expansion less than 50 ppm/K; (2) a Tg greater than 180° C.; (3) a Df less than 0.007; (4) a Dk less than 3.3; and (d) a tensile strength greater than 90 MPa.

In some non-limiting embodiments, the crosslinked resin prepared herein exhibits a coefficient of thermal expansion less than 40 ppm/K, in some non-limiting embodiments less than 30 ppm/K, in some non-limiting embodiment less than 20 ppm/K, and in some non-limiting embodiments less than 10 ppm/K.

In some non-limiting embodiments, the crosslinked resin prepared herein exhibits a Tg greater than 180° C., in some non-limiting embodiments greater than 190° C. in some non-limiting embodiments greater than 200° C., in some non-limiting embodiments greater than 210° C., in some non-limiting embodiments greater than 220° C., in some non-limiting embodiments greater than 230° C., in some non-limiting embodiments greater than 240° C., and in some non-limiting embodiments greater than 250° C.

In some non-limiting embodiments, the crosslinked resin prepared herein exhibits a Df less than 0.006, in some non-limiting embodiments less than 0.005, in some non-limiting embodiments less than 0.004, in some non-limiting embodiments less than 0.002, and in some non-limiting embodiments less than 0.001.

In some non-limiting embodiments, the crosslinked resin prepared herein exhibits a Dk less than 3.2, in some non-limiting embodiments less than 3.1, in some non-limiting embodiments less than 3.0, in some non-limiting embodiments less than 2.9, in some non-limiting embodiments less than 2.8, in some non-limiting embodiments less than 2.7, in some non-limiting embodiments less than 2.6, in some non-limiting embodiments less than 2.5, in some non-limiting embodiments less than 2.4, in some non-limiting embodiments less than 2.3, in some non-limiting embodiments less than 2.2, in some non-limiting embodiments less than 2.1, and in some non-limiting embodiments less than 2.0.

In some non-limiting embodiments, the crosslinked resin prepared herein exhibits a tensile strength greater than 100 MPa, in some non-limiting embodiments greater than 110 MPa, in some non-limiting embodiments greater than 120 MPa, in some non-limiting embodiments greater than 130 MPa, in some non-limiting embodiments greater than 140 MPa, in some non-limiting embodiments greater than 150 MPa, in some non-limiting embodiments greater than 160 MPa, in some non-limiting embodiments greater than 170 MPa, in some non-limiting embodiments greater than 180 MPa, in some non-limiting embodiments greater than 190 MPa, and in some non-limiting embodiments greater than 200 MPa.

A non-limiting example of a method for preparing a crosslinked resin comprising the soluble polyimide resin disclosed herein comprises the following steps in order: (a) coating the liquid composition as disclosed herein onto a matrix; (b) soft-baking the coated matrix at one or more preselected temperatures for one or more preselected time intervals; (c) exposing the coated matrix to UV radiation at a preselected wavelength and a preselected dosage for a preselected time interval; (d) treating the coated, UV-radiated matrix at a plurality of pre-selected temperatures for a plurality of pre-selected time intervals: (e) allowing the coated, UV-radiated, heat-treated matrix to cool; and (f) developing the coating via solvent bath and rinsing.

Liquid compositions of the present disclosure may be prepared by combining one or more of the soluble polyimides of the present disclosure, any organic solvents, water or additional components and a photoactive compound as a curing agent in any order. The organic solvents are the same as those described above. When the present compositions contain the photoactive compound, such as a diazonaphthoquinone, an onium salt or photoinitiator, it is preferred that the curing agent is first dissolved in a suitable organic solvent or aqueous alkali, then combined with one or more present polymers and any optional surfactant, and then combined with any optional adhesion promoter. Selection of a suitable photoactive compound is within the ordinary level of skill in the art.

In some non-limiting embodiments, the liquid compositions of the present disclosure may be coated or deposited on a substrate by any suitable method. The substrates are the same as those described above. Suitable methods for coating the present compositions can include, but are not limited to, spin-coating, curtain coating, spray coating, roller coating, dip coating, vapor deposition, and lamination such as vacuum lamination and hot roll lamination, among other methods. In the semiconductor manufacturing industry, spin-coating is a preferred method to take advantage of existing equipment and processes. In spin-coating, the solids content of the composition may be adjusted, along with the spin speed, to achieve a desired thickness of the composition on the surface to which it is applied.

When the liquid compositions of the present disclosure do not contain an adhesion promoter, the surface of the substrate to be coated with the present compositions may optionally first be contacted with a suitable adhesion promoter or vapor treated. Various vapor treatments known in the art may increase the adhesion of the polymers of the present disclosure to the substrate surface, such as plasma treatments. In certain applications, it may be preferred to use an adhesion promoter to treat the substrate surface prior to coating the surface with the present compositions. The adhesion promoter is the same as those described above.

Typically, the liquid compositions of the present disclosure are spin-coated at a spin speed of 400 to 4000 rpm. The amount of the present compositions dispensed on the wafer or substrate depends on the total solids content in the composition, the desired thickness of the resulting layer, and other factors well-known to those skilled in the art. When a film or layer of the present compositions is cast by spin-coating, much (or all) of the solvent evaporates during deposition of the film. Preferably, after being disposed on a surface, the composition is heated (soft-baked) to remove any remaining solvent. Typical baking temperatures are from 80 to 120° C., although other temperatures may be suitably used. Such baking to remove residual solvent is typically done for approximately one to five minutes, although longer or shorter times may suitably be used.

The compositions of the present disclosure are typically cured by heating for a period of time. Suitable curing temperatures range from 140 to 300° C.; or from 170 to 250° C. Typically curing times range from 1 to 600 minutes, or from 30 to 240 minutes, or from 30 to 120 minutes.

Generally, the thickness of the formed resin composition layer is equal to or greater than the thickness of the conductive layer. Since the thickness of the conductive layer in the circuit substrate is generally within a range of 5-70 μm, the resin composition layer generally has a thickness of 10-100 μm.

There is further provided a surface treated metallic foil wherein at least one surface of the metallic foil comprises a surface treatment comprising (a) one or more soluble polyimide resins; (b) one or more inorganic fillers; (c) one or more adhesion promoters; and (d) one or more initiators; wherein the one or more adhesion promoters are capable of functioning as a crosslinker with one or more components of the surface treatment.

Non-limiting examples of the metallic foils are selected from the group consisting of copper foils, nickel foils, cobalt foils, titanium foils, stainless steel foils, and others as are known to those with skill in the art.

In one embodiment, the liquid compositions comprising the polymer described herein can be coated onto copper foils. In some non-limiting embodiments, the result is a surface treated copper foil wherein at least one surface of the surface treated copper foil comprises (a) 15-90 wt. % of one or more soluble polyimide resins; (b) 5-75 wt. % of one or more crosslinking compounds; (c) 0-5 wt. % of one or more photoinitiators; (d) 0-5 wt. % of one or more oxidation catalysts; (e) 0-65 wt. % of one or more solvents; (f) 0-60 wt. % of one or more additional resins; (g) 0-10 wt. % of one or more surface leveling agents; (h) 0-70 wt. % of one or more organic or inorganic fillers and (i) 0-25 wt. % of one or more adhesion promoters. Embodiments associated with the composition, (a)-(i), are generally the same as those disclosed elsewhere herein for the corresponding components in resins, compositions, etc.

Copper foils include rolled annealed (RA) copper foils and electrodeposited (ED) copper foils. Because these foils are manufactured using a variety of methods, they may differ from each other in terms of mechanical properties, flexibility, and required copper roughing treatment. Generally, an ED copper foil has a matte surface (deposit surface) and a shiny surface (drum surface); whereas a RA copper foil has both surfaces being smooth. As the present copper foils are intended for use in flexible copper-clad laminates (FCCLs) and flexible printed circuit boards (FPCBs) for high frequency and/or high speed applications, suitable copper foils are surface-treated copper foils that are derived from raw copper foils that have been subjected to conventional surface treatments at least on one of their surfaces.

When a copper foil is incorporated into a flexible copper-clad laminate, the side of the copper foil facing toward a dielectric layer is referred as the “lamination side”. The opposite side of the “lamination side” is referred as the “resist side”. Provided that the present surface-treated copper foil has only one treated surface, then the treated surface becomes the lamination side when it is incorporated into a flexible copper-clad laminate.

By controlling current density, and/or plating time, and/or temperature of plating bath, and/or additives of plating solution, the surface-treated copper foil may have different grain size, surface roughness, and thickness.

In some non-limiting embodiments, the copper foils used herein are selected from the group consisting of Mitsui MT 18FL (1.5 μm with 18 μm carrier), BF-NN-HT, BFL-NN-HT, BFL-NN-Z, etc.

In some non-limiting embodiments of the invention, the present surface-treated copper foil preferably has a cross-sectional average grain size of 2.5 μm or less, or 2.0 μm or less.

From the viewpoint of ensuring proper adhesion without increasing the conductor loss, the at least one treated surface of the surface-treated copper foil has a surface roughness (Sz, ten-point mean roughness) of 2.5 μm or less, or 2.0 μm or less, as measured by a laser microscope. The surface roughness (Sz) is measured by using a laser microscope according to ISO 25178.

The lamination side and/or the resist side of the present surface-treated copper may be implemented with a nodulation layer, a passivation layer, and/or an adhesion-promotion layer to enhance the adaptability of copper foil for use in FPCs. The surface properties of the resist side of the surface-treated copper foil are subject to many subsequent printed circuit fabrication processes such as micro-etch, acid rinse, brown oxide, black oxide, pre-solder-mask treatment, etc. It follows that the surface roughness, nodule density, and total amount of the non-copper metal elements are criteria for the lamination side of the present surface-treated copper foil. In some non-limiting embodiments, the at least one treated surface of the surface-treated copper foil comprises a nodulation layer having a nodule density of 300 or less pieces/25 m²; or 200 or less pieces/25 μm²; or 100 or less pieces/25 μm²; or 50 or less pieces/25 μm².

After the nodule electrodeposition treatment, one or more passivation treatments can be applied on one or both surfaces of the copper foil to provide additional desired properties such as anti-tarnishing, thermal resistance, and chemical resistance, etc. The passivation layers generally include non-copper metal elements such as zinc, nickel, chromium, cobalt, molybdenum, tungsten, and combinations thereof.

When the present surface-treated copper foil is incorporated into a flexible copper-clad laminate, the adhesion between the copper foil and the dielectric layer consists of a mechanical adhesion from the roughness of the copper foil but also a chemical bond from the adhesion promoter, if the adhesion-promotion layer is present. Generally, the final surface treatment is to form an adhesion-promotion layer by treating with a known adhesion promotor such as a phosphorous- or silane-based coupling agent, and the like. After completion of the adhesion-promotor treatment, moisture can be removed by an electric heater to obtain the surface-treated copper foils of the invention.

In some non-limiting embodiments, a structure is formed comprising the surface treated metallic foil as disclosed herein. The structure comprises a substrate having a metallic surface and the surface treatment disposed on the metallic surface, the surface treatment comprising the cured bulk polyimide resin and the inorganic filler, wherein at least a portion of the inorganic filler is bonded to the cured bulk polymer material; wherein the dielectric layer comprises a first region adjacent to the metallic surface. The structure further comprises a second region adjacent to the first region and opposite to the metallic surface, wherein the first region comprises a relatively lower amount of the inorganic filler and the second region comprises a relatively higher amount of the inorganic filler. The formation of such a structure can improve adhesion between the metallic foil and the surface treatment and has been described, for example, in KR 10-2422883 B1.

The preparation of surface-treated copper foils is further illustrated in the Examples section.

There is further provided a dry film comprising a soluble polyimide resin comprising: (a) one or more tetracarboxylic acid component residues; (b) one or more diamine component residues; and (c) one or more endcapping compounds; wherein: the one or more endcapping compounds comprise one or more crosslinking groups.

Specific embodiments associated with the (a) one or more tetracarboxylic acid component residues; (b) one or more diamine component residues; and (c) one or more endcapping compounds; wherein: the one or more endcapping compounds comprise one or more crosslinking groups are the same as those disclosed above herein.

In the preparation of such dry films, the compositions disclosed herein can be cast via a slot die coater or other suitable apparatus to form a dry film desirable for microelectronic applications. The cast films can be soft baked to remove residual solvent for 30 seconds to 10 minutes at temperatures of 70-150° C., or 90-120° C. The soft baked film can then be subjected to a curing condition of 150-250° C. for 30 minutes to 4 hours.

In other non-limiting embodiments, layers of the liquid compositions of the present disclosure may also be formed as a dry film and disposed on the surface of a substrate by lamination. In lamination-based processes when the adhesive film has a protective film with thickness between 1-40 μm; the protective film is first removed, then the adhesive film and the circuit substrate are preheated, if desired, and the adhesive film is compression-bonded to the circuit substrate while pressing and heating. In some non-limiting embodiments, there is suitably adopted a method in which the adhesive film is laminated on the circuit substrate under reduced pressure by a vacuum lamination method. Non-limiting lamination conditions can include: a compression bonding temperature (lamination temperature) of 70-140° C., a compression bonding pressure of 1-11 kgf/cm² (9.8×10⁴-107.9×10⁴ N/m²), and a reduced pressure of 20 mmHg (26.7 hPa) or less in terms of a pneumatic pressure. The lamination method may be batch- or continuous-mode using rolls. The vacuum lamination can be performed using a commercially available vacuum laminator. Examples of the commercially available vacuum laminator include a vacuum applicator manufactured by Nichigo-Morton Co., Ltd., a vacuum pressure laminator manufactured by Meiki Co., Ltd., a roll type dry coater manufactured by Hitachi Industries Co., Ltd., and a vacuum laminator manufactured by Hitachi AIC Inc.

In some non-limiting embodiments, the surface roughness of the metallic foil is 50-1000 nm, in some non-limiting embodiments 100-1000 nm, in some non-limiting embodiments 150-1000 nm, and in some non-limiting embodiments 200-1000 nm. In some non-limiting embodiments, the metallic foil has a thickness of 1-2.5 μm, in some non-limiting embodiments 1-5.0 μm, in some non-limiting embodiments 1-10 μm, and in some non-limiting embodiments 1-20.0 μm.

In some non-limiting embodiments, the dry film to metallic foil has an adhesion energy G1c of 60-80 J/m², in some non-limiting embodiments 70-90 J/m², in some non-limiting embodiments 80-100 J/m², and in some non-limiting embodiments >100 J/m²; where G1c refers to the adhesion energy at the onset of crack propagation. In some non-limiting embodiments, the peel strength of the dry film to the metallic foil is >0.3 N/mm, in some non-limiting embodiments >0.4 N/mm, in some non-limiting embodiments >0.5 N/mm, in some non-limiting embodiments >0.6 N/mm, and in some non-limiting embodiments >0.7 N/mm.

The lamination step of performing heating and pressing under reduced pressure can be carried out using a general vacuum hot press machine. For example, the lamination step can be carried out by pressing a metal plate such as a heated SUS plate from a support layer side. Lamination is generally done under a reduced pressure of 1×10⁻² MPa or less, and in some non-limiting embodiments 1×10⁻³ MPa or less. Although the heating and pressing can be performed in a single stage, it is generally advantageous to perform the heating and pressing separately by two or more stages so as to control bleeding of the resin. For example, the first-stage pressing may be performed at a temperature of 70-150° C. under a pressure of 1-15 kgf/cm² and the second-stage pressing may be performed at a temperature of 150-200° C. under a pressure of 1-40 kgf/cm². In some non-limiting embodiments, the pressing is performed at each stage for a period of 30-120 minutes. Examples of a commercially-available vacuum hot pressing machine include MNPC-V-750-5-200 (Meiki Co., Ltd.) and VH1-1603 (KITAGAWA SEIKI CO., LTD.).

The insulating layer can be formed on the circuit substrate by laminating the adhesive film on the circuit substrate, cooling the laminate to about room temperature, releasing the support in the case of releasing the support, and then thermally curing the resin composition layer. The appropriate condition for the thermal curing may be selected depending on the kind and content of each resin component in the resin compositions disclosed herein. In some non-limiting embodiments; the temperature and time for the thermal curing is selected from a range between 150-220° C. for 20-180 minutes, and in some non-limiting embodiments from a range between 160-210° C. for 30-120 minutes.

After forming the insulating layer, the support is then released in situations where the support had not been released before curing. Thereafter, the insulating layer formed on the circuit substrate is perforated as necessary to form a via hole or a through-hole. The perforation can be performed, for example, by a one or more methods known to those with skill in the art including drill, laser, plasma, or the like. In some non-limiting embodiments, perforation is achieved using a laser such as a carbon dioxide gas laser or a YAG laser.

Subsequently, the conductive layer is formed on the insulating layer by dry plating or wet plating. Non-limiting examples of dry plating methods include vapor deposition, sputtering, and ion plating. For wet plating, the surface of the insulating layer is sequentially subjected to a swelling treatment with a swelling solution, a roughening treatment with an oxidant, and a neutralization treatment with a neutralization solution to form convex-concave anchor. The swelling treatment with the swelling solution can be performed by immersing the insulating layer into the swelling solution at 50-80° C. for 5-20 minutes. Non-limiting examples of the swelling solution include an alkali solution and a surfactant solution. Examples of the alkali solution may include a sodium hydroxide solution and a potassium hydroxide solution. Commercially available swelling solution include Swelling Dip Securiganth P and Swelling Dip Securiganth SBU, (Atotech Japan K. K.). The roughening treatment with an oxidant can be performed by immersing the insulating layer into an oxidant solution at 60-80° C. for 10-30 minutes. Non-limiting examples of the oxidant include an alkaline permanganate solution in which potassium permanganate or sodium permanganate is dissolved in an aqueous solution of sodium hydroxide, dichromate, ozone, hydrogen peroxide/sulfuric acid, and nitric acid. The concentration of permanganate in an alkaline permanganate solution may be approximately 5 to 10% by weight. Examples of a commercially available oxidant include an alkaline permanganate solution such as Concentrate Compact CP and Dosing Solution Securiganth P (Atotech Japan K. K.). The neutralization treatment with a neutralization solution can be performed by immersing the insulating layer into the neutralization solution at 30-50° C. for 3-10 minutes. In some non-limiting examples, the neutralization solution can be an acidic aqueous solution. Examples of a commercially available neutralization solution include Reduction Solution Securiganth P (Atotech Japan K. K.).

The conductive layer may alternatively be formed by forming a plating resist with a reverse pattern of the conductive layer and performing only electroless plating. As a subsequent patterning method, a subtractive method or a semi-additive method may be used which are known to those skilled in the art.

There is further provided a multilayered printed wiring board, comprising: an insulating layer which is formed of a soluble polyimide resin comprising: (a) one or more tetracarboxylic acid component residues; (b) one or more diamine component residues; and (c) one or more endcapping compounds; wherein: the one or more endcapping compounds comprise one or more crosslinking groups; and a conductive layer formed by plating. Specific embodiments for the soluble polyimide resin and conductive layer are the same as those disclosed above herein.

The present disclosure is also directed to a wide variety of electronic devices comprising at least one layer of the dielectric films of the present application on an electronic device substrate. The electronic device substrate can be any substrate for use in the manufacture of any electronic device. Exemplary electronic device substrates include, without limitation, semiconductor wafers, glass, sapphire, silicate materials, silicon nitride materials, silicon carbide materials, display device substrates, epoxy mold compound wafers, circuit board substrates, and thermally stable polymers.

Although methods and materials similar or equivalent to those described herein can be used in the practice or testing of the present invention, suitable methods and materials are described below. In addition, the materials, methods, and examples are illustrative only and not intended to be limiting. All publications, patent applications, patents, and other references mentioned herein are incorporated by reference in their entirety.

### Examples

The concepts described herein will be further illustrated in the following examples, which do not limit the scope of the invention described in the claims. Materials:

All diamines, dianhydrides and reagents for polyimide syntheses were obtained from TCI America, Inc. and Sigma Aldrich. (Di)anhydride, (di)amine, polyimide and related designations used in this disclosure include: 6FDA (4,4′-hexafluoroiso-propylidenebisphthalic dianhydride), BPDA (3,3′,4,4′-biphenyl tetracarboxylic dianhydride), FDA (9,9′-bis(4-aminophenyl)fluorene), TFMB (2,2′-bis(trifluoromethyl) benzidine), BPADA (4,4′-bisphenol A dianhydride), APB-133 (1,3′-Bis (3-aminophenoxy) benzene), ODPA (4,4-oxydiphthalic anhydride), (4-ethynylaniline) (4-EA), (bis(3-aminopropyl) terminated poly(dimethyl-siloxane) (av Mn-2500)), DAMA (2,4-Diamino-6-diallylamino-1,3,5-triazine), 4AS (4-amino styrene), DMAC (dimethylacetamide), and PAA (polyamic acid). All other solvents and chemicals were received from Fisher Scientific and used as received without additional purification.

Copper foil 18 μm thick was subjected to a roughening etch treatment MEC CZ8101 (a product of MEC Company Ltd.), to a roughness of 400 nm average as measured by optical microscope.

### Molecular Weight Determination:

### (1) Polyimide Resins:

A Waters Model Breeze™ including pump and injector was used for polyimide resin molecular weight measurements. The mobile phase consisted of dimethylacetamide with 0.1% (wt/v) lithium chloride and 0.025% (wt/v) para-toluenesulfonic acid. The separation columns were a set of two Shodex GPC KD806 styrene-divinylbenzene gel, one Waters Styragel HR 0.5, and one Waters Styragel HR1. The column temperature was 40° C., the flow rate was 1.0 ml/min, the detector was a 2414™ differential refractometer with a 10 microliter size cell from Waters. The sample concentration was 1.0 mg/ml and the sample injection volume was 0.100 ml. Molecular weight was determined by polystyrene standards. The system used to gather and process data was Breeze™ v.2 from Waters.

Molecular weight distribution and average molecular weights were measured by GPC method with relative calibration. The samples were prepared by placing 5.0 mg polymer solids into 20 ml bottle, adding 5.0 mL eluent (N,N-dimethylacetamide with 0.1% Lithium Chloride and 250 ppm Toluene sulfonic acid), and mixing the solution until it was thoroughly dissolved and clear. Then, 2 ml of the solution was filtered into 2 ml injection vial through 0.2 PTFE filter. 100 microliters of sample solution were injected into the Waters Model Breeze™ using a syringe. Test results as reported were obtained by comparison to a calibration curve. All test methodology and subsequent reporting are complainant with OECD Guideline for Testing of Chemicals 118, as recommended by EPA document 744-B-97-001, “Polymer Exemption Guidance Manual.”

### (2) Arylcyclobutenes and Other Non-Polyimide Resins:

Polymer samples were prepared as a 0.5 wt. % solution in tetrahydrofuran and filtered through a 0.2 μm Teflon filter. The mobile phase was 0.5% triethylamine, 5% methanol and 94.5% tetrahydrofuran. The columns used were Waters Styragel HR5E 7.8×300 mm column lot number 0051370931. Injection volume was 100 microliters and run time was 27 minutes. Molecular weight data are reported relative to polystyrene standards.

### Test Methods

### (1) Dielectric Properties:

The IPC test method TM-650 2.5.5.13 (Revised 01/07) was used to determine dielectric properties of free-standing films using copper split cylinder resonators machined such that they possessed an empty cavity frequency of 10 GHz each and either a Keysight N5224A PNA or a Rohde & Schwarz ZNB40 network analyzer. The film geometry was such that the substrate extended beyond the diameter of the two cylindrical cavity sections. Although the dielectric substrate thickness can vary from 0.01 mm to 5.0 mm, a substrate thickness of 0.03 mm was used in these studies. Free-standing films were placed in the cavity of the split cylinder resonator and the resonant frequency and quality factor of the TE011 resonant mode were measured using the network analyzer. Relative permittivity (Dk) and loss tangent (Df) of the films were calculated from the TE011 resonant mode using custom software written in MATLAB.

### (2) Thermomechanical and Gravimetric Analysis:

Free standing films were cleaved into 10 mm by 25 mm geometry and placed in a TA Instruments dynamic mechanical analyzer Q800 instrument at a strain rate of 0.06%, preload force of 1 newton, and a frequency of 1 hertz. The temperature was equilibrated at 50° C. then increased to 250° C. at a rate of 5° C. per minute. The glass transition temperature value was taken as the maximum value of the curve of tan 6. Thermomechanical analysis was performed on a TA Instruments Thermomechanical Analyzer Q400 in a tensile mode. Samples were heated at a rate of 5° C. to 200° C., then brought down to −50° C., then back up to 250° C. at the same rate. The coefficient of thermal expansion was determined to be the linear change in dimension from 25° C. to 150° C. in the last cycle.

### (3) Peel Testing, 18 μm Copper Foil

Once copper foil samples had been cured, peel strips were scored on the coupon one centimeter wide with a suitable blade, then the copper strip was peeled off at a ninety-degree angle on an Intron tensile tester at a rate of 50 mm/min. The peel force value in kilogram force per centimeter was calculated. Values above 0.75 kgf/cm were considered excellent, while values below 0.4 kgf/cm were considered unacceptable for the embodiments disclosed herein.

### (4) Instron Testing

Free standing films were cleaved into 51 mm by 13 mm strips and were placed into either an Instron 5943 or an Instron 68SC-1 Universal Testing System. The samples were testing in accordance to ASTM-D822-12, Standard Test Method for Tensile Properties of Thin Plastic Sheeting. Data were collected and analyzed using Intron Bluehill® software.

### General Soluble Polyimide Resin Synthesis

Into a three-necked reaction vessel equipped with a PTFE stirring shaft, an O-ring and a bearing assembly were inserted under nitrogen. The desired amino compounds were dissolved in DMAc at room temperature for most diamines. In certain examples, the DMAC is warmed to an appropriate temperature to dissolve all of the diamines added. To the stirring solution of diamine(s), the desired dianhydride monomers were added portion-wise to the reaction mixture such that the internal temperature did not exceed the desired temperature. The reaction mixture was stirred until the resulting polyamic acid solution was within the desired viscosity range.

To the polyamic acid solution, acetic anhydride and β-picoline were added. The temperature of the reaction mixture was increased to 80° C. and the reaction was held at that temperature for approximately 3 h and then stirred overnight. The resulting polyimide was then isolated as a powder by precipitation from water. The polymer was then rinsed with methanol and dried. The polyimide was isolated as a white powder and characterized by GPC and NMR spectroscopy.

### Preparation of Soluble PI Resin 1—SPI1

Preparation of soluble styrene terminated polyimide copolymer of (ODPA//TFMB/APB-133/4AS-100//49/49/4). Into a 1-liter reaction flask equipped with a nitrogen inlet and outlet and mechanical stirrer were charged 31.38 g of trifluoromethyl benzidine (TFMB) and 175 g of dimethylacetamide (DMAC). The mixture was agitated under nitrogen at room temperature for about 30 minutes to dissolve the TFMB. Afterwards, 28.65 g of 1,3,3-aminophenoxy benzene (APB-133) and 0.95 grams of 4-amino styrene (4AS) were added with 50 g DMAC. After the amines dissolved, 60.80 g oxydiphthalic anhydride (ODPA) was added to the reaction with stirring along with 59 g DMAC. The addition rate of the dianhydrides was controlled so as to keep the maximum reaction temperature <40° C. The dianhydride dissolved and reacted, and the polyamic acid (PAA) solution was stirred for ˜24 hr. After this, ODPA was added in 0.310 g increments to raise the molecular weight of the polymer and viscosity of the polymer solution in a controlled manner. Brookfield cone and plate viscometry was used to monitor the solution viscosity by removing small samples from the reaction flask for testing. A total of 1.24 g of ODPA was added. The reaction proceeded for an additional 72 hours at room temperature under gentle agitation to allow for polymer equilibration. Final polyamic acid viscosity was 10,600 cP.

50.4 grams of acetic anhydride and 45.99 grams of 3-methylpyridine were added to the polyamic acid copolymer solution which was then heated at 80° C. for 4 hrs. The mixture was precipitated into water (1000 mL×2) and washed with methanol (1000 mL). The isolated polyimide solid was dried in vacuo at 70° C. for 2-3 days. The solid was later dissolved and formulated in various solvents (NMP, DMAc, and cyclopentanone).

### Preparation of Soluble PI Resin 2—SPI2

Preparation of soluble styrene terminated polyimide copolymer of (ODPA//TFMB/APB-133/2,4-diamino-6-diallylamino-1,3,5-triazine (DAMA)/4AS 100//46.5/46.5/5/4). Into a 500 mL reaction flask equipped with a nitrogen inlet and outlet and mechanical stirrer were charged 22.34 g of trifluoromethyl benzidine (TFMB) and 150 g of dimethylacetamide (DMAC). The mixture was agitated under nitrogen at room temperature for about 30 minutes to dissolve the TFMB. Afterwards, 20.39 g of 1,3,3-aminophenoxy benzene (APB-133), 1.55 g of 2,4-diamino-6-diallylamino-1,3,5-triazine (DAMA) and 0.72 grams of 4-amino styrene (4AS) were added with 36 g DMAC. After the amine dissolved, 45.6 g oxydiphthalic anhydride (ODPA) was added to the reaction with stirring along with 25 g DMAC. The addition rate of the dianhydrides was controlled, so as to keep the maximum reaction temperature <40° C. The dianhydride dissolved and reacted and the polyamic acid (PAA) solution was stirred for ˜24 hr. After this, ODPA was added in 0.233 g increments to raise the molecular weight of the polymer and viscosity of the polymer solution in a controlled manner. Brookfield cone and plate viscometry was used to monitor the solution viscosity by removing small samples from the reaction flask for testing. A total of 0.931 g of ODPA was added. The reaction proceeded for an additional 72 hours at room temperature under gentle agitation to allow for polymer equilibration. Polyamic acid viscosity was 829 cP.

To the polyamic acid mixture, 37.67 grams of acetic anhydride and 34.36 grams of 3-methylpyridine was added to the polyamic acid copolymer solution and heated at 80 C for 4 hrs. The mixture was precipitated into water (1000 mL×2) and washed with methanol (1000 mL). The isolated polyimide solid was dried in vacuo at 70° C. for 2-3 days. The solid was later dissolved and formulated in various solvents (NMP, DMAc, and cyclopentanone).

### Preparation of Soluble PI Resin 3—SPI3

Preparation of soluble styrene terminated polyimide copolymer of BPADA//APB-133/TFMB/4AS 100//42.5/42.5/30. Into a 1 L reaction flask equipped with a nitrogen inlet and outlet, mechanical stirrer and thermocouple were charged 16.33 g (0.051 moles) of TFMB, 14.91 g (0.051 moles) of APB-133, 4.29 g (0.036 moles) of 4AS and 217 mL DMAC. The mixture was agitated under nitrogen at room temperature for about 30 minutes. Afterwards, 61.21 g (0.1176 moles) of BPADA was added slowly in portions to the stirring solution of the diamines. After completion of the dianhydride addition an additional 24 mL of DMAC were used to wash in any remaining dianhydride powder from containers and the walls of the reaction flask. The resulting mixture was stirred for 24 hrs. Separately, a 5% solution of BPADA in DMAC was prepared and added in small amounts (ca. ˜6.25 g) every 24 hrs for 4 days. A total of 24.98 g of BPADA in DMAC solution was added. The resulting reaction was allowed to stir at room temperature under gentle agitation for additional 1-2 days. The imidization of the PAA took place by heating the solution to 40° C. followed by addition of 56.04 g of acetic anhydride and 51.12 g of 3-methypyridine. The reaction mixture was then heated to 80° C. for 5-7 hours. After cooling to room temperature, the polymer solution was poured into 4 L MeOH in a blender and rapidly stirred to pulverize the polymer solid. The pulverized polymer solid was allowed to stir in the blender for 10 mins before collection by filtration. The polymer powder was air dried overnight and further dried under vac at 60° C. over 2 days. 91 grams amount of polymer was obtained.

The soluble polyimide resins prepared included:
SPI1: ODPA//TFMB/APB-133/4AS 100//49/49/4
SPI2: ODPA//TFMB/APB-133/DAMA/4AS 100//46.5/46.5/5/4
SPI3: BPADA//APB-133/TFMB/4AS 100/42.5/42.5/30
SPI4: ODPA/6FDA//TFMB/Priamine™ 1075/4-AS 85/15//91/05/08
SPI5: ODPA//APB-133/TFMB/DAMA/4-EA 100//46.5/46.5/05/04
SPI6: ODPA//APB-133/TFMB/M1309/4-AS 100//46/46/04/08
SPI7: BPADA//APB-133/4-AS 100//85/30
   with associated properties in Table 1.

TABLE 1
Properties of Soluble Polyimides

| Example # | Polymer Composition | Mn | Mw | PDI | CTE | Df |
|---|---|---|---|---|---|---|
| SPI4 | ODPA/6FDA//TFMB/Priamine | 26,014 | 75,084 | 2.89 | 18 | 0.006 |
| | 1075/4-AS (85/15//91/05/08) | | | | | |
| SPI5 | ODPA//APB-133/TFMB/DAMA/4- | 11,792 | 35,930 | 3.05 | 27 | 0.005 |
| | EA (100//46.5/46.5/05/04) | | | | | |
| SPI6 | ODPA//APB-133/TFMB/M1309/ | 14,705 | 64,267 | 4.37 | 25 | 0.005 |
| | 4-AS 100//46/46/04/08 | | | | | |
| SPI7 | BPADA//APB-133/4-AS | 8,339 | 14,534 | 1.74 | 29 | 0.003 |
| | (100//85/30) | | | | | |
| SPI2 | ODPA//TFMB/APB-133/DAMA/4AS | 15,274 | 37,649 | 2.46 | 27 | 0.006 |
| | 100//46.5/46.5/5/4 | | | | | |

### Preparation of Comparative PI Resin 1—CPI1

A polyimide comprising ODPA, BisP, and TFMB with a Mn of approximately 72,500 and a Mw of approximately of 314,300 vs. a polystyrene standard was placed in cyclopentanone such that if the material fully dissolved, a 20 wt % solution would have been formed. After rolling the vial for an extended period of time, less than 5 wt % of the polymer redissolved.

### General Formulation and Free-Standing Film Preparation and Testing

Into a 20 mL scintillation vial, dry polyimide polymer powder and N-methyl-2-pyrrolidone (NMP) are combined. The vial is capped and sealed, then the mixture is rolled for the appropriate amount of time to dissolve the polyimide polymer in solution, usually 24-48 hr. After the initial mixing period is complete, additional components, such as crosslinkers, adhesion promoters, etc. are added to the polyimide solution. The vial containing the formulation is then rolled for an additional 24 hr to prepare a homogenous solution. The formulation is filtered through a 3-μm polypropylene filter membrane using a plastic syringe. For formulations containing particle fillers or other inhomogeneous components, these components are added after filtration and the formulation is rolled to disperse the insoluble components, usually an additional 6-24 hr.

To prepare a film, an automatic drawdown bar (DDB) coater is used. The desired substrate for coating is placed onto the automated coater table and secured. The formulation is dispensed onto the substrate and a DDB with an appropriate gap to provide the desired film thickness is used to form the film on substrate. Immediately after coating, the substrate with the film is transferred onto a hot plate set to 80° C. and allowed to soft bake for 10 minutes. After soft baking is completed, the coated substrate is removed from the hot plate and allowed to cool to room temperature.

The soft-baked film was cured using a belt furnace under nitrogen atmosphere. Curing the film took place on the desired substrate. It was passed through the belt furnace through a series of heating zones to achieve a maximum curing temperature of either 200° C. for 60 min or 300° C. for 20 min. Typical curing profile with a maximum cure temperature of either 200° C. or 300° C. with a belt speed of 0.7 inches per inch are shown in Table 2.

TABLE 2
Cure Temperature Profiles

| | 200° C. Max Cure | 300° C. Max Cure |
|---|---|---|
| | Set Temperature of | Set Temperature of |
| Zone | Heating Zone (° C.) | Heating Zone (° C.) |
| 1 | 95 | 95 |
| 2 | 130 | 130 |
| 3 | 165 | 165 |
| 4 | 200 | 200 |
| 5 | 200 | 200 |
| 6 | 200 | 225 |
| 7 | 200 | 300 |
| 8 | 200 | 300 |

Cured films were delaminated from their substrates by either submerging the coated substrate in deionized water for at least 24 hr or until the film was released from the substrate. Alternatively, the films were placed into a pressure cooker for 18-24 hr at 15-20 psi and 125° C., after which they were cooled to room temperature. Delaminated films were then dried either in air or in a vacuum oven set to 70° C. and a pressure of <1 inHg for 18-24 hr.

### Preparation of Free-Standing Film 1—FSF1

A formulation containing polyimide SPI3 (3.002 g) and crosslinker MIR-3000 (1.294 g) in NMP (7.977 g) was prepared, coated, soft-baked, and cured according to the procedure outlined above. This generated a free-standing film with a thickness of 20.4 μm, Dk (10 GHz) of 2.83, Df (10 GHz) of 0.0038, average tensile modulus of 1.85 GPa (max 2.35 GPa), average tensile strength of 70.5 MPa (max 74.0 MPa), and average Eb of 6.4% (max 7.9%).

### Preparation of Free-Standing Film 2—FSF2

A formulation containing polyimide SPI3 (3.000 g) and crosslinker SR454 (1.283 g) in NMP (7.954 g) was prepared, coated, soft-baked, and cured according to the procedure outlined above. This generated a free-standing film with a thickness of 27.2 um, Dk (10 GHz) of 2.88, Df (10 GHz) of 0.0151, average tensile modulus of 1.84 GPa (max 2.02 GPa), average tensile strength of 69.8 MPa (max 88.5 MPa), average Eb of 7.6% (max 12.0%).

### Preparation of Free-Standing Film 3—FSF3

A formulation containing polyimide SPI3 (3.000 g), crosslinker MIR-3000 (0.643 g), and crosslinker Kowa DCP-M (0.643 g) in NMP (7.959 g) was prepared, coated, soft-baked, and cured according to the procedure outlined above. This generated a free-standing film with a thickness of 31.8 um, Dk (10 GHz) of 2.66, Df (10 GHz) of 0.0046, average tensile modulus of 2.32 GPa (max 2.62 GPa), average tensile strength of 83.6 MPa (max 125.7 MPa), average Eb of 8.9% (max 10.8%). Film properties are collected in Table 3.

TABLE 3
Free Standing PI Film Properties

| | | | | Tensile | Tensile | Tensile | Tensile | | |
|---|---|---|---|---|---|---|---|---|---|
| | T | Dk | Df | Modulus | Modulus | Strength | Strength | Eb (%) | Eb (%) |
| Example | (um) | (10 GHz) | (10 GHz) | (GPa) avg. | (GPa) max. | (MPa) avg. | (MPa) max. | avg. | max. |
| FSF1 | 20.4 | 2.83 | 0.0038 | 1.85 | 2.35 | 70.5 | 74.0 | 6.4 | 7.9 |
| FSF2 | 27.2 | 2.88 | 0.0151 | 1.84 | 2.02 | 69.8 | 88.5 | 7.6 | 12.0 |
| FSF3 | 31.8 | 2.66 | 0.0046 | 2.32 | 2.62 | 83.6 | 125.7 | 8.9 | 10.8 |

### Preparation of Free-Standing Film 4—FSF4

A formulation containing polyimide SPI3 (3.000 g), crosslinker MIR-3000 (0.643 g), and crosslinker Kowa DCP-M (0.643 g) in NMP (7.959 g) was prepared, coated, soft-baked, and cured according to the procedure outlined above. This generated a free-standing film with a thickness of 31.8 um, Dk (10 GHz) of 2.66, Df (10 GHz) of 0.0046, average tensile modulus of 2.32 GPa (max 2.62 GPa), average tensile strength of 83.6 MPa (max 125.7 MPa), average Eb of 8.9% (max 10.8%).

### General Procedures for Preparation of PI-based Formulations Including Silica Formulation Containing 50 wt. % of Silica:

To a container, 35.4 wt. % of a soluble polyimide (DM-120) was added followed by adding a solvent such as cyclopentanone to make a formulation of 45 wt. % solids of total mass. After the polyimide was well-mixed and fully dissolved in the solvent, 5 wt. % of triallyl cyanurate (TAC) or triallyl isocyanurate (TAIC), 2.5 wt. % of Homide 116, 2.5 wt. % of a Sartomer (SR454), 3.5 wt. % of SPV-100, 1 wt. % of a thermal radical initiator, dicumyl peroxide (DCP), and 0.1 wt. % of a surfactant, Polyfox 656, were mixed well with the polyimide solution. Finally, 50 wt. % of an Admatechs silica, 5GX-CM1 with 0.5 mm average particle size and 5 mm size top cut (70 wt. % in methyl ethyl ketone) were added. The resulting mixture was homogenized before coating.

### Formulation Containing 70 wt. % of Silica:

To a container, 21.24 wt. % of a soluble polyimide (DM-120) was added followed by adding a solvent such as cyclopentanone to make a formulation at 45 wt. % of total component mass. After the polyimide was mixed well with the solvent, 3 wt. % of triallyl cyanurate (TAC) or triallyl isocyanurate (TAIC), 1.5 wt. % of Homide 116, 1.5 wt. % of a Sartomer (SR454), 2.1 wt. % of SPV-100, 0.6 wt. % of a thermal radical initiator, dicumyl peroxide (DCP), and 0.06 wt. % of a surfactant, Polyfox 656, were mixed well with the polyimide solution. Finally, 70 wt. % of a mixture of Admatechs silica, SC2050-MTM/5GX-CM1 (1:1, w/w) with 0.5 mm average particle size and 5 mm size top cut (70 wt. % in methyl ethyl ketone) were added. The resulting mixture was homogenized before coating.

### Preparation of PI-Coated Copper—RCC1 and RCC2:

Soluble polyimide-based formulations were prepared by mixing all components including polyimide base resin, crosslinkers, surfactant, a thermal radical initiator, and inorganic fillers such as functionalized silica particles in cyclopentanone, generally targeting at 45% solids, followed by rolling overnight to ensure complete mixing. The formulation solutions were then draw-down coated onto Nan Ya N738G release PET substrate for dry film or a thin copper foil for resin coated copper (RCC) via a steel bar with a 200-micron gap at a speed of 6 mm/s followed by soft baking the films at 90° C. for 3 minutes on a hot plate to ensure <1% residual solvent in films by GC. After soft bake, the dry film or RCC are covered with PE film for storage.

Soluble polyimide-based formulations were also coated via. a slot die coater (i.e., nTact nRad Extrusion Deposition System) using a 2-mil shim with a coating gap of 150 μm and a relative velocity of 13 mm per second. The coating dispensing rate was 238 μL per second with a dispense delay of 1000 ms at start of coat using a chuck. The soft bake condition was at 80° C. for 12 minutes in a convection oven. The substrates included 1.5 and 18 μm BFL-NN-HT copper foils and Nan Ya N738G release PET.

The dry films or RCC were laminated onto a suitable substrate via a Meiki (MVLP 500/600) Laminator using a first stage vacuum of approximately 2 hPa for 30 seconds, at 95-110° C. with a pressure of 0.95-1.00 MPa for 60 seconds through a rubber contact, and a second stage with a steel plate using a pressure of 1.2 MPa for 60 seconds.

After lamination, dry film samples were cured using the SierraTherm belt furnace (model #7K9-74C122-8ANLIR) for 40 minutes at 135° C. and 60 minutes at 200° C. under nitrogen (less than 100 ppm of oxygen). Next, the specimen was released, and PET was removed, yielding a freestanding film sample that could be cleaved into desirable dimension for analysis.

For copper foil peel tests, samples were either coated directly onto the corresponding copper foil (i.e., RCC) followed by laminating onto CCL board or laminated a dry film with dielectric film facing down onto the corresponding copper foil followed by removing PET and laminating the other side of the dielectric film onto a CCL board. The laminated specimens were then cured following identical belt furnace conditions as described previously.

Compositions of PI-coated copper as prepared herein are collected in Table 4.

TABLE 4
PI Coated Copper Formulations

| | Weight % | | | | |
|---|---|---|---|---|---|
| | Soluble | | | | |
| | PI | Cross- | Thermal | | |
| Example | Resin⁽¹⁾ | linker⁽²⁾ | Initiator⁽³⁾ | Surfactant | Silica⁽⁴⁾ |
| RCC1 | 35.40 | 5.00 TAC | 1.00 DCP | 0.10 Polyfox | 25 SC2050-MTM |
| | | 2.50 BMI-TMH | | 656 | 25 5GX-CM1 |
| | | 2.50 SR454 | | | |
| | | 3.50 SPV-100 | | | |
| RCC2 | 21.24 | 3.00 TAC | 0.60 DCP | 0.06 Polyfox | 35 SC2050-MTM |
| | | 1.50 BMI-TMH | | 656 | 35 5GX-CM1 |
| | | 1.50 SR454 | | | |
| | | 2.10 SPV-100 | | | |

⁽¹⁾Soluble PI Resin—SPI3 as described and prepared herein
⁽²⁾Crosslinkers—TAC is triallyl cyanurate, BMI-TMH is a bismaleimide, SR454 is ethoxylated 3-trimethylolpropane triacrylate, and SPV-100 is a phosphazene
⁽³⁾Thermal Initiator—DCP is dicumyl peroxide
⁽⁴⁾Silica—Silica SC2050-MTM is spherical silica with average particle diameter of 0.5 μm and propyl methacrylate ligand treatment, Silica 5GX-CM1 is 0.5 μm average diameter silica, treated with a propyl anhydride trimethoxy silane coupling agent

Associated propertied are collected in Table 5.

TABLE 5
Resin Coated Copper Properties

| | Tg | Dk | Df | CTE1 | CTE2 | | | Moisture | |
|---|---|---|---|---|---|---|---|---|---|
| Example | (DMA ° C.) | (10 GHz) | (10 GHz) | (ppm/K)⁽¹⁾ | (ppm/K)⁽²⁾ | Peel-1⁽³⁾ | Peel-2⁽⁴⁾ | Ads⁽⁵⁾ | Flex⁽⁶⁾ |
| RCC1 | 197 | 3.0 | 0.005 | 24 | 90 | 0.8 | 0.8 | 0.27 | ++ |
| RCC2 | 192 | 3.3 | 0.003 | 11 | 27 | 0.57 | 0.54 | 0.20 | + |

⁽¹⁾mTMA, 50-150° C.
⁽²⁾mTMA, 200-275° C.
⁽³⁾Peel to 18 mm Cu foil (N/mm)
⁽⁴⁾Peel to 18 mm Cu foil Post HAST (N/mm)
⁽⁵⁾Moisture adsorption 60° C./60% RH (wt %)
⁽⁶⁾Flex is a qualitative assessment of film flexibility. While both films were flexible, RCC1 exhibited superior flexibility

RCC1 and RCC2 are observed to exhibit high T_{g} and peel strength on Cu foil with relatively low CTE while maintaining film flexibility and dielectric properties.

### Preparation of PI-Coated Copper—RCC3-RCC7:

Soluble polyimide-based formulations were prepared and coated onto copper foils as described herein above. Compositions are those reported in Table 6.

TABLE 6
PI-based Formulations

| | Weight % | | | | |
|---|---|---|---|---|---|
| | Soluble | | | | |
| | PI | Cross- | Thermal | | |
| Example | Resin⁽¹⁾ | linker⁽²⁾ | Initiator⁽³⁾ | Surfactant | Silica⁽⁴⁾ |
| RCC3 | 35.40 | 5.00 TAC | 1.00 DCP | 0.10 Polyfox | 50 5GX-CM1 |
| | | 2.50 BMI-TMH | | 656 | |
| | | 2.50 SR454 | | | |
| | | 3.50 SPV-100 | | | |
| RCC4 | 35.40 | 5.00 TAC | 1.00 DCP | 0.10 Polyfox | 25 SC2050-MTM |
| | | 2.50 BMI-TMH | | 656 | 25 5GX-CM1 |
| | | 2.50 SR454 | | | |
| | | 3.50 SPV-100 | | | |
| RCC5 | 38.90 | 5.00 TAC | 1.00 DCP | 0.10 Polyfox | 50 5GX-CM1 |
| | | 2.50 BMI-TMH | | 656 | |
| | | 2.50 SR454 | | | |
| RCC6 | 35.40 | 5.00 TAC | 1.00 DCP | 0.10 Polyfox | 25 SC2050-MTM |
| | | 2.50 BMI-TMH | | 656 | 25 5GX-CM1 |
| | | 2.50 SR454 | | | |
| | | 3.50 SPV-100 | | | |
| RCC7 | 35.40 | 5.00 TAC | 1.00 DCP | 0.10 Polyfox | 25 SC2050-MTM |
| | | 2.50 BMI-TMH | | 656 | 25 5GX-CM1 |
| | | 2.50 SR454 | | | |
| | | 3.50 SPV-100 | | | |

⁽¹⁾Soluble PI Resin—SPI3 as described and prepared herein
⁽²⁾Crosslinkers—TAC is triallyl cyanurate, BMI-TMH is a bismaleimide, SR454 is ethoxylated 3-trimethylolpropane triacrylate, and SPV-100 is a phosphazene
⁽³⁾Thermal Initiator—DCP is dicumyl peroxide
⁽⁴⁾Silica—Silica SC2050-MTM is spherical silica with average particle diameter of 0.5 μm and propyl methacrylate ligand treatment, Silica 5GX-CM1 is 0.5 μm average diameter silica, treated with a propyl anhydride trimethoxy silane coupling agent

Associated properties are collected in Table 7.

TABLE 7
Peel Strength for RCC3-RCC7

| | Film Thickness | Coating | Peel Strength |
|---|---|---|---|
| Example | (μm) | Process** | (N/mm) |
| RCC3 | 30* | Bar Coat | 0.8141 |
| RCC5 | 30* | Bar Coat | 0.7881 |
| RCC6 | 16 | Slot Die Coat | 0.8703 |
| RCC6 | 25 | Slot Die Coat | 0.8526 |
| RCC7 | 28 | Slot Die Coat | 0.8892 |

*Estimated average thickness by bar coat
**The film thickness is uniform by slot die coat

Measured peel strength is observed to increase when SPV-100 is used in coating compositions. In addition, the use of mixed silicas is observed to increase peel strength for the coating compositions prepared herein.

### Impact of Copper Foil Selection on Observed Peel Strength

Formulation RCC4 was coated onto a variety of copper foils using the above procedures with properties as reported in Table 8.

TABLE 8
Properties of RCC4 Coated on Copper Foils

| | | Sa | Surface | Peel |
|---|---|---|---|---|
| | | Roughness | Resistivity | Strength |
| Example | Cu Foils | (nm) | (mOhm/sq) | (N/mm) |
| RCC4 | Mitsui MT 18FL* | 212 | 62.5 | 0.8165 |
| | (1.5 mm with 18 mm | | | |
| | carrier) | | | |
| | BF-NN-HT** | 236 | 47.33 | 0.8225 |
| | BFL-NN-HT** | 202 | 46.67 | 0.7726 |
| | BFL-NN-Z** | 165 | 47.23 | 0.8236 |

*Unknown surface treatment
**Surface treated with silane adhesive promoter

Measured peel strength and surface resistivity are observed to be a function of the copper foil chosen and the presence or absence of foil surface treatment.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this disclosure to match a minimum value from one range with a maximum value from another range and vice versa.

What is claimed is:

1. A soluble polyimide resin comprising:
(a) one or more tetracarboxylic acid component residues;
(b) one or more diamine component residues; and
(c) one or more endcapping compounds;
wherein:
the one or more endcapping compounds comprise one or more crosslinking groups.

2. The soluble polyimide resin of claim 1, wherein the one or more endcapping compounds comprising one or more crosslinking groups is selected from the group consisting of aliphatic endcapping compounds, aromatic endcapping compounds, heteroaromatic endcapping compounds, alkynl endcapping compounds, alkenyl endcapping compounds, maleimide endcapping compounds, vinyl endcapping compounds, allylic endcapping compounds, cyanate ester endcapping compounds, and ester endcapping compounds.

3. The soluble polyimide resin of claim 2, wherein the one or more crosslinking groups are selected from the group consisting of radical crosslinking groups, cationic crosslinking groups, anionic crosslinking groups, crosslinking groups capable of forming homopolymers by crosslinking with themselves, crosslinking groups capable of forming heteropolymers by crosslinking with other crosslinking groups, and combinations thereof.

4. The soluble polyimide resin of claim 3, wherein the one or more crosslinking groups are selected from the group consisting of allyl groups, vinyl groups, alkynal groups, alkenyl groups, (meth)acrylate groups, benzocyclobutene groups, maleimide groups, allylic groups, cyanate ester groups, and ester groups.

5. The soluble polyimide resin of claim 1, wherein the soluble polyimide resin is selected from the group consisting of:
ODPA//TFMB/APB-133/4AS 100//49/49/4;
ODPA//TFMB/APB-133/DAMA/4AS 100//46.5/46.5/5/4;
BPADA//APB-133/TFMB/4AS 100//45/45/20;
BPADA//APB-133/TFMB/4AS 100//42.5/42.5/30;
ODPA/6FDA//TFMB/Priamine™ 1075/4-AS 85/15//91/05/08;
ODPA//APB-133/TFMB/DAMA/4-EA 100//46.5/46.5/05/04;
ODPA//APB-133/TFMB/M1309/4-AS 100//46/46/04/08;
BPADA//APB-133/4-AS 100//85/30; and
BPADA//APB133/TFMB/1-(4-aminophenyl)-1H-pyrrole-2,5-dione) 100//42.5/42.5/30

6. A method for preparing the soluble polyimide resin of claim 1, wherein the method comprises the following steps in order:
(a) dissolving one or more diamines in a high-boiling, polar, aprotic solvent;
(b) adding one or more endcapping compounds to the solution prepared in (a);
(c) adding one or more dianhydrides to the solution prepared in (b);
(d) stirring the solution prepared in (c) for a first predetermined period of time;
(e) heating the solution prepared in (d) to a first predetermined temperature and optionally adding a solution of one or more imidization catalysts;
(f) heating the solution prepared in (e) to a second predetermined temperature and stirring for a second predetermined period of time; and
(g) cooling the solution prepared in (f) and isolating the solid polyimide resin.

7. The soluble polyimide resin of claim 1, wherein the soluble polyimide resin has:
(a) Mn less than 80,000;
(b) Mw less than 150,000;
(c) a loss tangent less than 0.007; and
(d) a coefficient of thermal expansion less than 50 ppm/K.

8. A liquid composition comprising two or more of the following:
(a) 15-90 weight % of one or more soluble polyimide resins;
(b) 5-75 weight % of one or more crosslinking compounds;
(c) 0-5 weight % of one or more photoinitiators or thermal radical initiators;
(d) 0-5 weight % of one or more oxidation catalysts; and
(e) 0-65 weight % of one or more solvents.

9. The liquid composition of claim 8, wherein the liquid composition additionally comprises one or more of the following:
(f) 10-60 wt. % of one or more additional resins;
(g) 0-10 wt. % of one or more surface leveling agents;
(h) 0-70 wt. % of one or more organic or inorganic fillers; and
(i) 0-25 wt. % of one or more adhesion promoters.

10. A crosslinked resin comprising the liquid composition of claim 9.

11. A surface-treated metallic foil wherein at least one surface of the surface-treated metallic foil comprises a surface treatment comprising:
(a) one or more soluble polyimide resins;
(b) one or more inorganic fillers;
(c) one or more adhesion promoters; and
(d) one or more initiators;
wherein:
the one or more adhesion promoters are capable of functioning as a crosslinker with one or more components of the surface treatment.

12. A structure comprising the surface treated metallic foil of claim 11, wherein the structure comprises:
a substrate having a metallic surface and the surface treatment disposed on the metallic surface, the surface treatment comprising the cured bulk polyimide resin and the inorganic filler, wherein at least a portion of the inorganic filler is bonded to the cured bulk polymer material; wherein the dielectric layer comprises:
a first region adjacent to the metallic surface; and
a second region adjacent to the first region and opposite to the metallic surface, wherein the first region comprises a relatively lower amount of the inorganic filler and the second region comprises a relatively higher amount of the inorganic filler.

13. A dry film comprising the soluble polyimide resin of claim 1.

14. The dry film of claim 13, wherein the dry film comprises:
(a) 5 wt. % to 50 wt. % of the soluble polyimide resin;
(b) greater than or equal to 50 wt. % of one or more surface functionalized and crosslinkable inorganic fillers; and
(c) 15 wt. % to 30 wt. % of one or more additives selected from the group consisting of photoinitiators, thermal radical initiators, crosslinkers, additional resins, surface leveling agents, and adhesion promoters.

15. The dry film of claim 14, wherein:
the one or more surface functionalized and crosslinkable inorganic fillers have an equivalent average diameter that is less than 1 μm and an upper-cut diameter less than 5 μm; and
the one or more additives consist of one or more thermal radical initiators and one or more crosslinkers comprising allyl, vinyl, (meth)acrylate, and maleimide groups.

16. The dry film of claim 15, wherein the dry film is cured at a temperature less than or equal to 200° C.

17. The dry film of claim 16, wherein the dry film is coated or laminated onto a metallic foil; wherein
(a) the surface roughness of the metallic foil is 200-1000 nm;
(b) the thickness of the metallic foil is 1.0-5.0 μm;
(c) the dry film to metallic foil has an adhesion energy G1c>100 J/m²; and
(d) the peel strength of the dry film to the metallic foil is >0.5 N/mm.

18. A multilayered printed wiring board comprising an insulating layer which is comprised of the soluble polyimide resin of claim 1 and a conductive layer formed by plating.

19. The multilayered printed wiring board of claim 18, wherein the insulating layer comprises:
(a) 5 wt. % to 50 wt. % of the soluble polyimide resin;
(b) greater than or equal to 50 wt. % of one or more surface functionalized and crosslinkable inorganic fillers; and
(c) 15 wt. % to 30 wt. % of one or more additives selected from the group consisting of additional resins, surface leveling agents, and adhesion promoters.
